(19) United States
(12) Patent Application Publication
(10) Pub. No.: US 2026/0271720 A1
(43) Pub. Date: Sep. 10, 2026

(54) SYSTEMS AND METHODS FOR LIQUID COOLING OF A HEAT-GENERATING SEMICONDUCTOR DEVICE

(71) Applicant: Taiwan Semiconductor Manufacturing Company, LTD., Hsinchu (TW)

(72) Inventor: Yu-Hsun Li, Yunlin (TW)

(21) Appl. No.: 19/073,325

(22) Filed: Mar. 7, 2025

(51) Int. Cl. H01L 23/44

(52) U.S. Cl. CPC H10W 40/30

(57) ABSTRACT

Packages are formed from a heat-generating device and a plurality of MEMS cooling devices attached thereto. Such packages can be cooled using dielectric liquids. Each MEMS cooling device includes an actuator bonded to a carrier wafer. The carrier wafer includes a plurality of holes extending through a substrate. The actuators vibrate and increases the rate of liquid flow past the heat-generating device, improving the cooling effect. Some cooling devices vibrate in one direction, and some cooling devices vibrate in the opposite direction, to further enhance liquid flow.

### BACKGROUND

Micro-electromechanical systems (MEMS) is a technology that employs miniature mechanical and electro-mechanical elements (e.g., devices or structures) on a wafer substrate. Devices or structures that can be used in MEMS include sensors, actuators, and other structures. MEMS devices may be used in a wide range of applications.

MEMS structures can be made using photolithographic patterning processes that use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of a dual-phase immersion cooling system.

FIG. 1B is a side view of the dual-phase immersion cooling system.

FIG. 2 is a side view of a single-phase immersion cooling system.

FIG. 3 is a side cross-sectional view of an interposer, showing various locations where the MEMS cooling device could be attached.

FIG. 4 is a schematic perspective view of a first package formed from a heat-generating device with a plurality of MEMS cooling devices attached thereto, in accordance with some embodiments of the present disclosure.

FIG. 5A is a plan view of a MEMS actuator through line A-A of FIG. 4.

FIG. 5B is a cross-sectional view through a portion of a first embodiment of the MEMS cooling device as indicated in FIG. 5A.

FIG. 5C is a magnified plan view of an arm array of the MEMS actuator.

FIG. 5D is a magnified side cross-sectional view of the micromechanical arm array, in accordance with some embodiments of the present disclosure.

FIG. 5E is an X-axis view of the perimeter region of the carrier wafer through line E-E of FIG. 5B. Three openings are illustrated.

FIGS. 6A-6D are plan views of different embodiments of a carrier wafer of the MEMS cooling device through line B-B of FIG. 4.

FIG. 7A is a plan view of an adhesive layer and the heat-generating device through line C-C of FIG. 4.

FIG. 7B is a plan view of another adhesive layer and the heat-generating device through line C-C of FIG. 4.

FIGS. 8A-8D are plan views showing different arrangements of MEMS cooling devices on a heat-generating device.

FIG. 9 is a cross-sectional view through another embodiment of a package formed from a heat-generating device with a plurality of MEMS cooling devices attached thereto, in accordance with some embodiments of the present disclosure.

FIG. 10 is a flow chart illustrating a method for making or assembling a MEMS cooling device with a carrier wafer, and subsequently using the MEMS cooling device on a heat-generating device, in accordance with some embodiments.

FIGS. 11A-11B together are a flow chart illustrating a first method for making a MEMS actuator, in accordance with some embodiments.

FIG. 12 is a side cross-sectional view of a package used for making the MEMS actuator.

FIG. 13A is a plan view of the package after a first etching step. FIG. 13B is a side cross-sectional view of the package through line B-B of FIG. 13A. FIG. 13C is a side cross-sectional view of the package through line C-C of FIG. 13A. FIG. 13D is a side cross-sectional view of the package through line D-D of FIG. 13A.

FIG. 14 is a side cross-sectional view of the package after formation of a first dielectric layer.

FIG. 15 is a side cross-sectional view of the package after deposition of piezoelectric material over the top wafer to form two arrays of piezoelectric fingers.

FIG. 16A is a side cross-sectional view of the package after CMP of the piezoelectric material. FIG. 16B is a plan view.

FIG. 17 is a side cross-sectional view of the package after etching to remove the piezoelectric material from trenches.

FIG. 18 is a side cross-sectional view of the package after further addition to the first dielectric layer over the two arrays of fingers.

FIG. 19 is a side cross-sectional view of the package after partial etching of the first dielectric layer to expose portions of the top wafer.

FIG. 20 is a side cross-sectional view of the package after deposition of a first etch stop layer over the top wafer.

FIG. 21 is a side cross-sectional view of the package after formation of a second dielectric layer.

FIG. 22A is a side cross-sectional view of the package after partial etching of the second dielectric layer. FIG. 22B is a plan view.

FIG. 23 is a side cross-sectional view of the package after deposition of a second etch stop layer over the top wafer.

FIG. 24A is a side cross-sectional view of the package after etching of the etch stop layers to expose various portions of the top wafer. FIG. 24B is a plan view.

FIG. 25 is a side cross-sectional view of the package after deposition of metal.

FIG. 26A is a side cross-sectional view of the package after etching to form a metal cap. FIG. 26B is a plan view.

FIG. 27A is a side cross-sectional view of the package after formation of a passivation layer. FIG. 27B is a plan view.

FIG. 28A is a side cross-sectional view of the package after silicon etching of the top wafer to form a cavity below the micromechanical arm arrays. FIG. 28B is a plan view.

FIG. 29A is a side cross-sectional view of the package after annealing and the bottom wafer is removed, leaving the top wafer (i.e. the MEMS actuator). FIG. 29B is a plan view.

FIG. 30 is a flow chart illustrating a first method for making a carrier wafer, in accordance with some embodiments.

FIG. 31A is a plan view of the substrate with an initial mask that exposes a perimeter region when openings on the front side of the carrier wafer are desired. FIG. 31B is a Y-axis cross-sectional view through line B-B of FIG. 31A. FIG. 31C is a Y-axis cross-sectional view through line C-C of FIG. 31A.

FIG. 32 is a Y-axis cross-sectional view of the substrate after etching.

FIG. 33A is a plan view of the substrate with a first mask that exposes an intermediate region. FIG. 33B is a Y-axis cross-sectional view through line B-B of FIG. 33A.

FIG. 34 is a side cross-sectional view of the substrate after etching to form one or more cavities in the intermediate region.

FIG. 35 is a side cross-sectional view of the substrate with a second mask that exposes parts of the cavities.

FIG. 36 is a side cross-sectional view of the substrate after etching to form one or more holes that extend to the back side of the carrier wafer.

FIG. 37 is a side cross-sectional view of another embodiment of a MEMS cooling device, in accordance with some embodiments of the present disclosure. Here, the central region of the carrier wafer includes a plurality of steps extending downwards towards the intermediate region.

FIG. 38A is a plan view of a first example embodiment of the carrier wafer having a plurality of steps.

FIG. 38B is a plan view of a second example embodiment of the carrier wafer having a plurality of steps.

FIG. 39 is a flow chart illustrating a second method for making a carrier wafer, in accordance with some embodiments. The central region of the carrier wafer includes a plurality of steps.

FIG. 40 is a side cross-sectional view of the substrate after applying a first mask and forming a first step.

FIG. 41 is a side cross-sectional view of the substrate after applying a second mask and forming a first plateau.

FIG. 42 is a side cross-sectional view of the substrate after applying a third mask and forming a second plateau.

FIG. 43 is a side cross-sectional view of the substrate after applying a fourth mask and forming a third plateau.

FIG. 44 is a side cross-sectional view of the substrate after applying a fifth mask and forming trenches/floors between the plateaus.

FIG. 45 is a side cross-sectional view of the substrate after applying an optional sixth mask and forming holes in the intermediate region.

FIG. 46 is a magnified side cross-sectional view of the central region of the carrier wafer, showing more detail relating to the steps and trenches.

FIG. 47 is a flow chart illustrating another method for making a carrier wafer, in accordance with some embodiments. This is an alternate method for forming the central region with a plurality of steps.

FIG. 48 is a side cross-sectional view of the substrate after applying a first mask and forming a trench that includes a sloped sidewall in the central region and a cavity in the intermediate region.

FIG. 49 is a side cross-sectional view of the substrate after applying a second mask. The second mask covers the intermediate region and exposes trenches in the central region.

FIG. 50 is a side cross-sectional view of the substrate after etching to form trenches/floors between steps in the central region.

FIG. 51 is a side cross-sectional view of the substrate after removing the second mask.

FIG. 52 is a side cross-sectional view of the substrate after applying an optional third mask. The third mask covers the central region and exposes hole regions in the intermediate region.

FIG. 53 is a side cross-sectional view of the substrate after etching to form the holes and removing the third mask.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The disclosure refers to “length” and “width”. These terms should not be construed as implying the length must have a greater value than the width, and are not necessarily used consistently herein with respect to the axis in which they are measured.

The present disclosure relates to structures which are made up of different layers. When the terms “on” or “upon” or “over” are used with reference to two different layers (including the substrate), they indicate merely that one layer is on or upon or over the other layer. These terms do not require the two layers to directly contact each other, and permit other layers to be between the two layers. For example all layers of the structure can be considered to be “on” or “over” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The present disclosure relates to liquid cooling applications in which micro-electromechanical system (MEMS) devices are used for improving liquid flow past a heat-generating semiconductor device. Such MEMS cooling devices can include an actuator and a carrier wafer which are bonded together. The MEMS actuators convert energy, such as heat energy or electrical signals or liquid pressure differential, into physical motion or mechanical force. The carrier wafer is bonded to the actuator, and includes one or more holes through which liquid can flow. Vibration of the actuator causes liquid flow. When used in the presence of the heat-generating device, the liquid flow causes cooling liquid to move more quickly past the heat-generating device for higher heat transfer.

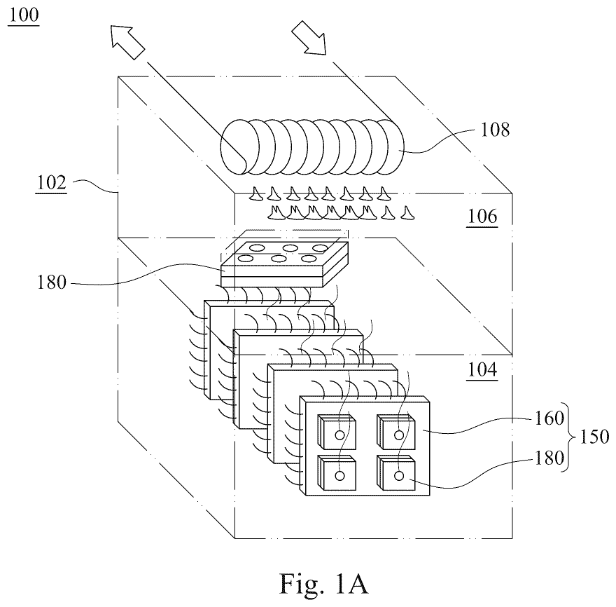

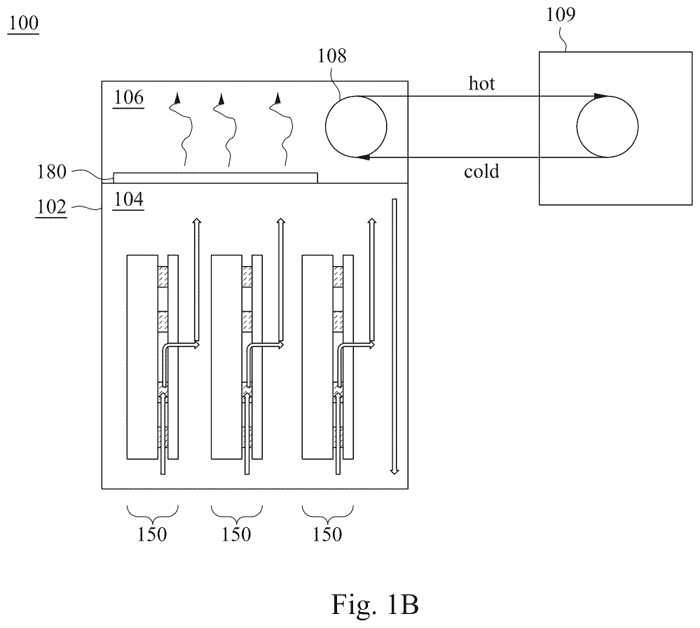

FIG. 1A and FIG. 1B are different views of a liquid cooling system, and in particular a dual-phase immersion cooling system 100. As illustrated here, the cooling system includes a housing 102 in which a cooling liquid 104 is placed. Four packages 150 formed by the combination of a heat-generating semiconductor device 160 and a plurality of MEMS cooling devices 180 are shown as being placed within the housing, and in particular within the cooling liquid. Also illustrated is a MEMS cooling device 180 that floats upon the cooling liquid. The housing also contains an airspace 106 at the top, which includes a condenser coil 108. In particular embodiments, the cooling liquid is a dielectric liquid which is not electrically conductive, but is thermally conductive.

In operation, the packages 150 generate heat. The MEMS cooling devices cause the cooling fluid to flow past the heat-generating device at a higher rate (e.g. gallons/minute) compared to the situation in which the MEMS cooling device is not present. The dielectric liquid eventually boils and turns into a gas. The phase change absorbs additional energy due to the heat of vaporization. The vapor condenses on the condenser coil 108, and returns to a liquid within the housing. A coolant within the condenser coil absorbs the heat energy and transfers the heat energy out of the housing and to a heat exchanger 109, where the heat is removed from the coolant. The coolant is then recycled to the condenser coil. Arrows are present to show fluid flow and temperature.

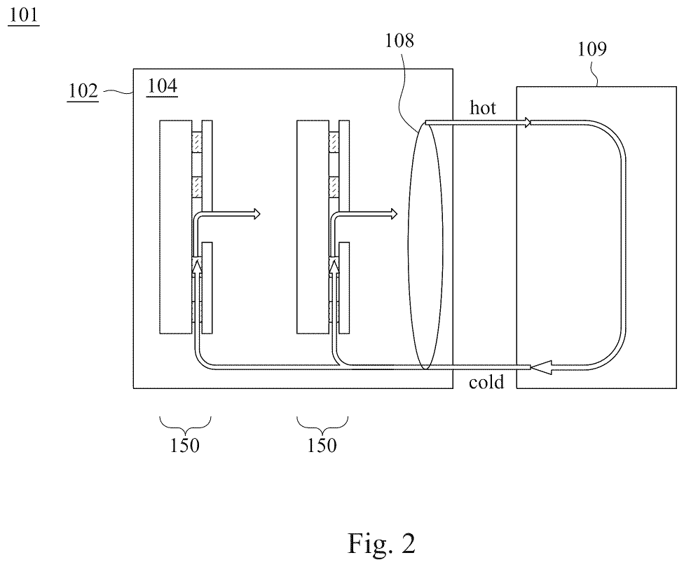

FIG. 2 is an illustration of a single-phase immersion cooling system 101. The system has the same components as the dual-phase system, but the cooling liquid fills the entire housing, and no airspace is present at the top. Otherwise, the system operates in the same manner.

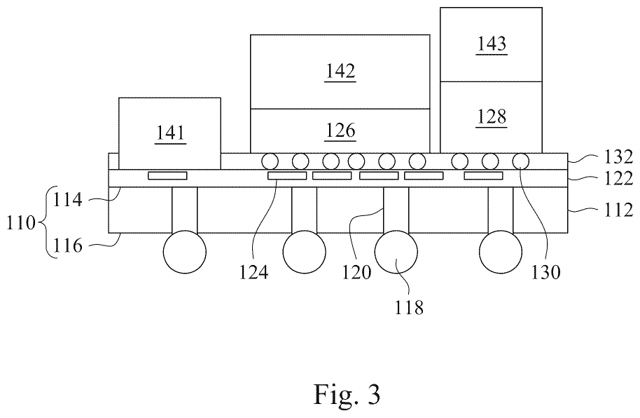

Referring now to FIG. 3, some examples of heat-generating devices are shown. An interposer 110 is shown here that includes a substrate 112 having through-substrate vias (TSVs) 120 extending between a first side 114 and a second side 116 of the substrate. A redistribution layer (RDL) 122 is formed over the first side 114 of the substrate. The RDL includes one or more layers of electrical interconnects that permit components to communicate with each other. The electrical interconnects are separated by a dielectric material. The RDL may be formed by several repeated steps of applying and patterning a dielectric layer, then applying and patterning a layer of electrically conductive materials. Bond pads 124 are illustrated on the surface of the RDL. Electrical connectors 118 are formed on the second side 116 of the substrate upon the TSVs 120. These may be, for example, lands, balls, pins, bumps, pillars, or other similar structures.

One or more chips are bonded to the interposer wafer substrate 112. Two different chips are illustrated here, for example a System-on-Chip (SOC) 126 and a memory chip 128. On an SoC, many electronic components are combined together on one common substrate. The SoC contains a semiconductor die, for example, a central processing unit (CPU) or a graphics processing unit (GPU). The memory chip may be, for example, high bandwidth memory (HBM). The chips 126, 128 are bonded, for example, through an interconnect layer 130 to the bond pads 124. An underfill material 132 fills any gaps between the chips 126, 128 and the interposer wafer substrate 112.

Three MEMS cooling devices 141, 142, 143 are illustrated in FIG. 3. The first MEMS cooling device 141 is attached to the interposer 110 itself, where passive devices such as resistors or inductors might generate heat. The second MEMS cooling device 142 is attached to the SoC 126. The CPU and GPU contained therein generate significant heat. The third MEMS cooling device 143 is attached to the memory chip 128, which can generate heat. It is noted that the MEMS cooling device is attached to a surface of the heat-generating device, but does not have to cover the entire surface to which it is attached. For purposes of illustration, only one MEMS cooling device is attached to the heat-generating device, although in practice a plurality of MEMS cooling device are attached to a heat-generating device.

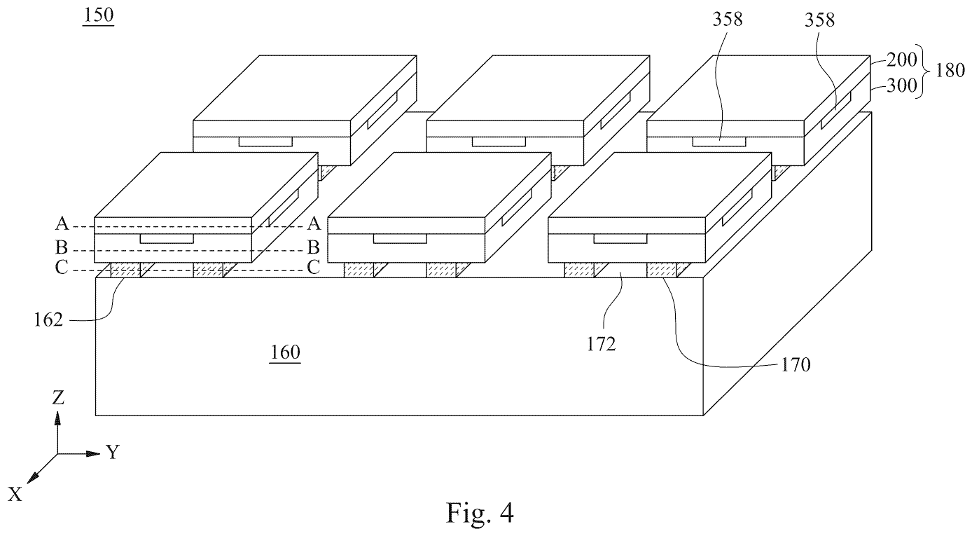

FIG. 4 is a schematic perspective view of a package 150 that includes a heat-generating device 160 with MEMS cooling devices 180 attached thereto, in accordance with some embodiments of the present disclosure. In this illustration, there are six MEMS cooling devices, arranged in a 2×3 array. Each MEMS cooling device 180 includes a MEMS actuator 200 bonded to a carrier wafer 300. The carrier wafer 300 is adhered to a surface 162 of the heat-generating device 160 through an adhesive layer 170. The adhesive layer is discontinuous, or in other words includes spaces 172 so that liquid can flow between the surface 162 of the heat-generating device 160 and the carrier wafer 300. As illustrated here, lateral openings 358 are also present in one or more sides of the carrier wafer 300.

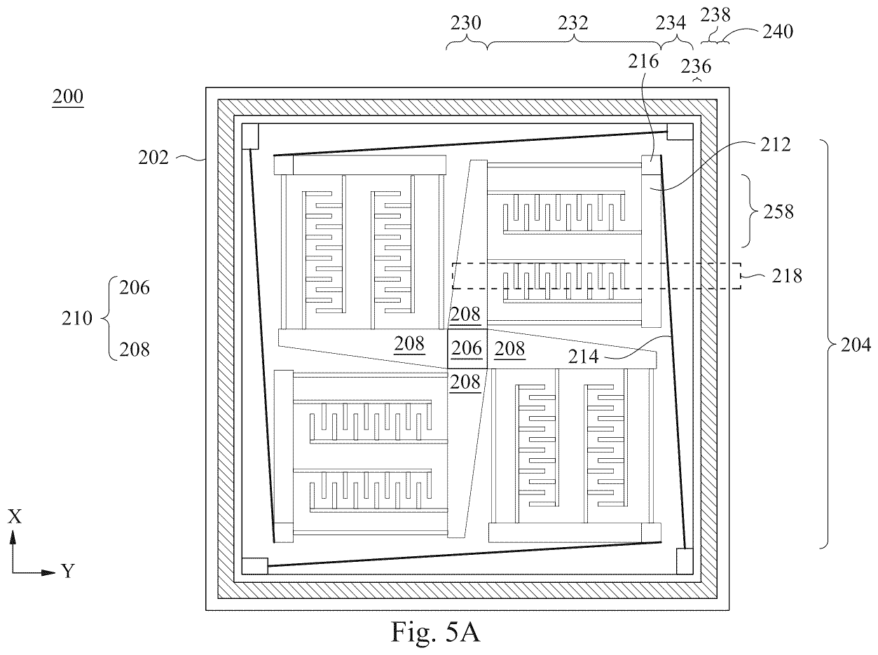

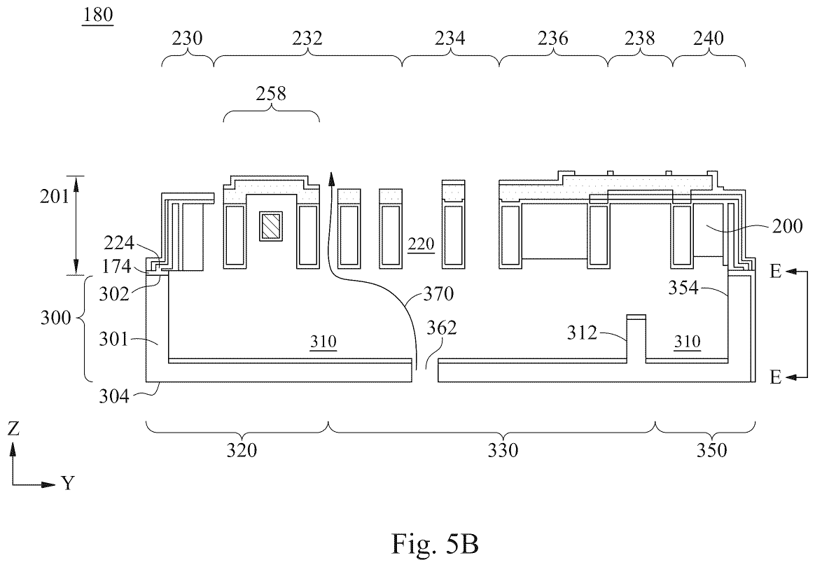

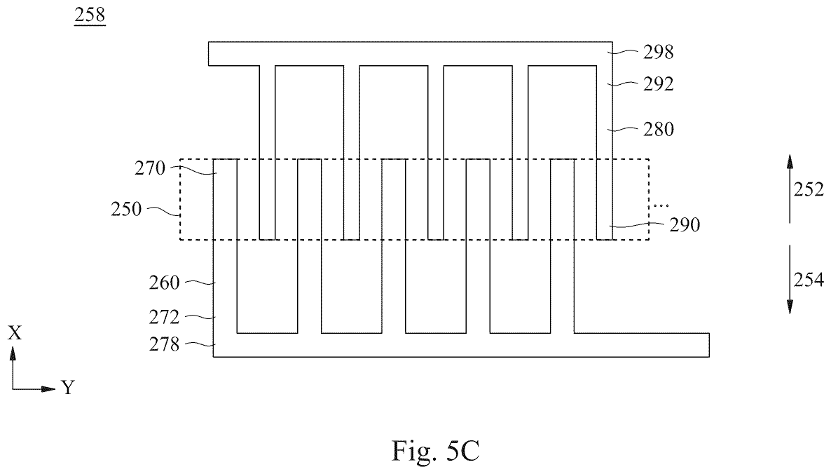

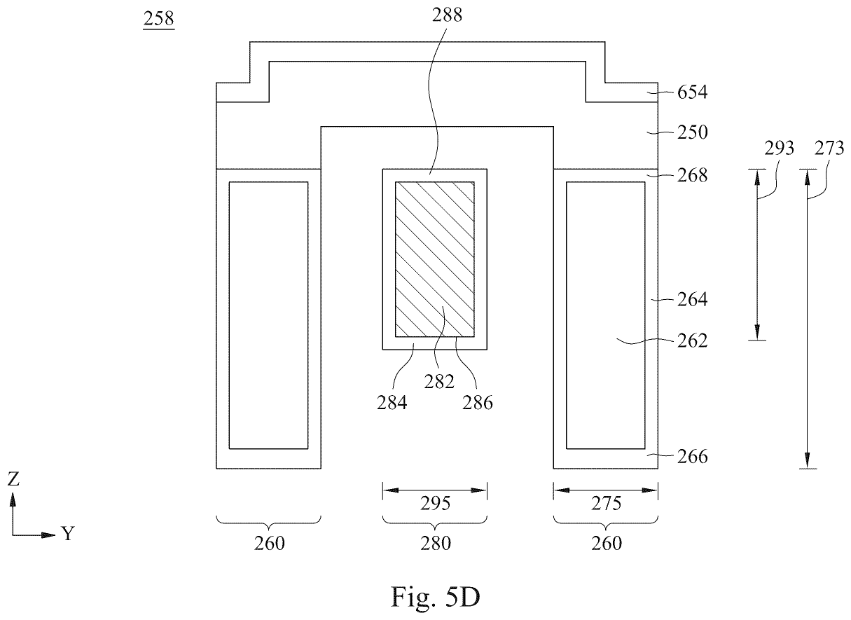

FIG. 5A is a plan view of the MEMS actuator 200 through line A-A of FIG. 4. FIG. 5B is a cross-sectional view through a portion of a first embodiment of the package as indicated by dashed box 218 in FIG. 5A. FIG. 5C is a magnified plan view of an arm array 258 of the MEMS actuator.

Referring to FIG. 5A and FIG. 5B, the MEMS cooling device 180 includes a MEMS actuator 200 and a carrier wafer 300, which are bonded together through a bonding layer 174. In FIG. 1B, the illustrated actuator 200 includes a four-sided frame 202 which surrounds and is spaced apart from a vibration component 204. The vibration component 204 includes an anchor 206 located at the center. As illustrated here, four anchor arms 208 extend from the anchor, and together they can be considered an anchor structure 210.

In FIG. 5A, the actuator 200 has multiple sections in the horizontal direction, which are labeled as an anchor arm section 230, a driving comb section 232, a hinge section 234, an inner frame section 236, a spring section 238, and an outer frame section 240. The anchor arm section 230 is part of the anchor arm 208. The inner frame section 236, spring section 238, and outer frame section 240 make up part of the frame 202 of the actuator. Micromechanical arm arrays 258 are located in the driving comb section 232. These illustrated sections together make up a quadrant of a MEMS actuator (the other three quadrants having the same structure, suitably rotated).

The anchor arm section 230 provides structural integrity and aids in supporting the driving comb section. The hinge section 234 allows for pivotal movement, or allows for the controlled rotation of other components relative to the driving comb section. The inner frame section 236 provides structural support and stability. The spring section 238 provides some elasticity to maintain the desired positioning and movement of the components, and also provides a restoring force to bring the components back to their original position after actuation. The outer frame section 240 generally provides structural integrity, protecting the internal components from some external and environmental forces.

The vibration component 204 can be described as having four quadrants, each quadrant being located between two anchor arms. Within each quadrant, an anchor arm 208 supports one or more micromechanical arm arrays 258 within a driving comb section 232 as previously described. As illustrated here, the driving comb section includes two micromechanical arm arrays, but any number of such arrays may be present. In particular embodiments, the driving comb section may contain from one to ten micromechanical arm arrays. The length of the driving comb section opposite the anchor arm 208 can serve as a support 212. A hinge 214 or cantilever traverses an open space to join the support 212 to a non-adjacent corner of the frame 202. Also located on each support is a separate mount point 216.

Referring now to FIG. 5B, an empty cavity 220 is present within the actuator 200. The micromechanical arm array 258 is disposed within the cavity and can move freely within the cavity. The cavity also extends continuously below the hinge section 234, the inner frame section 236, and the spring section 238. Two smaller empty cavities 310 are also present within the carrier wafer 300, which are generally located below the hinge section 234, the inner frame section 236, and the spring section 238. The cavity 220 in the actuator 200 is connected to the two smaller cavities 310 in the carrier wafer 300. Generally, the actuator 200 has a relatively lower thickness 201 (for example in the range of about 200 μm) which results in the actuator being very flexible.

Referring more specifically now to FIG. 5C and FIG. 5D, the micromechanical arm array 258 in the actuator contains two separate arrays of fingers, an array of first fingers 260 and an array of second fingers 280, which are made from a piezoelectric material. A metal cap 250 (shown as dashed box in FIG. 5C) is present above each array of fingers 260, 280.

The first fingers 260 extend in a first direction 252 and are joined to a first arm 278. The proximal ends 272 of the first fingers are joined to the first arm 278, and the distal ends 270 extend away from the first arm in a first direction 252. The second fingers 280 extend in a second direction 254 opposite the first direction and are joined to a second arm 298. The proximal ends 292 of the second fingers are joined to the second arm 298, and the distal ends 290 extend away from the second arm in the second direction 254. The arms are made from the same material as their fingers. The fingers 260, 280, extend in a first horizontal direction (i.e. X-axis, or longitudinal direction). The two arms 278, 298 extend in a second horizontal direction (i.e. Y-axis, or lateral direction). The other ends of the two arms are connected to the anchor arm section 230 and the outer frame section 240. Also illustrated is a metal cap 250 extending over both sets of fingers 260, 280, although only contacting one set of fingers.

The first fingers 260 are spaced apart laterally from each other. Similarly, the second fingers 280 are spaced apart laterally from each other. The first fingers 260 are laterally offset from the second fingers 280. In this plan view, the offset is reflected in the distal ends 270, 290 of the fingers 260, 280 being interposed or interlaced with each other. The fingers can vibrate in the X-axis, Y-axis, and/or Z-axis relative to each other.

FIG. 5D is a magnified side cross-sectional view of the micromechanical arm array 258. It is noted that this is an extremely simplified illustration for purposes of description only, and is not fully representative of the complete micromechanical arm array 258.

As illustrated here, each first finger 260 includes a core 262, which is formed from a piezoelectric material. A cover layer 264 is present around all sides of the core 262, and isolates the core from the cavity. The cover layer may act as an etch stop layer, and is generally made from a dielectric material. Each first finger also has a free end 266 (or bottom end) and a fixed end 268 (or top end). In this view, the first finger has a height 273 and a width 275.

Similarly, each second finger 280 includes a core 282, which is formed from a piezoelectric material. A cover layer 284 is present around all sides of the core 282, and isolates the core from the cavity. The cover layer may act as an etch stop layer, and is generally made from a dielectric material. Each second finger also has a free end 286 (or bottom end) and a fixed end 288 (or top end). The second finger has a height 293 and a width 295.

As illustrated here, the height 273 of the first finger is greater than the height 293 of the second finger. In some particular embodiments, the heights 273, 293 may independently range from about 150 micrometers (μm) to about 200 μm. Other ranges are also within the scope of the present disclosure. In particular embodiments, their heights differ by about ten (10) μm, including about 5 μm to about 20 μm.

The width 275 of the first finger and the width 295 of the second finger can be the same or different, as desired. In addition, the two fingers 260, 280 are illustrated as being located so their top surfaces are at the same height or level. Again, this is not required for operation of the micromechanical arm array.

A passivation layer 654 is present upon the top surface of the metal cap 250. As illustrated here, the metal cap 250 directly contacts the fixed ends 268 of the first array of fingers 260, and does not directly contact the fixed ends 288 of the second array of fingers 280. The free ends 266, 286 of both arrays of fingers are able to move freely below the metal cap.

Referring now to the carrier wafer 300 as illustrated in FIG. 5B, the carrier wafer 300 includes a central region 320, an intermediate region 330, and a perimeter region 350. The intermediate region is located between the central region and the perimeter region. Generally, the central region 320 of the carrier wafer is located below the anchor arm section 230 and some portion of the driving comb section 232. The intermediate region 330 of the carrier wafer is generally located below some portion of the driving comb section 232 and below the hinge section 234, the inner frame section 236, and some portion of the spring section 238. The perimeter region is generally located below the outer frame section 240 and perhaps some portion of the spring section 238. One or more cavities 310 are present extending from a first or front side 302 of the carrier wafer down into the substrate 301. Here, the cavities 310 are separated by a sidewall 312, and are present in the intermediate region and may also extend into the central region and/or the perimeter region. Finally, one or more holes 362 extend through the substrate to a second or back side 304 of the substrate. Here, one hole 362 is illustrated and is located within one cavity 310, although they may be present in any or all of the cavities. As a result, a fluid passageway 370 extends entirely through the carrier wafer 300 and through the MEMS actuator 200.

The perimeter region 350 includes a sidewall 354. As seen in the X-axis view of FIG. 5E, the sidewall 354 may include one or more lateral openings 358 (three are shown here, see also FIG. 4). These openings also permit liquid to flow into the open volume within the MEMS cooling device, which can desirably increase turbulence.

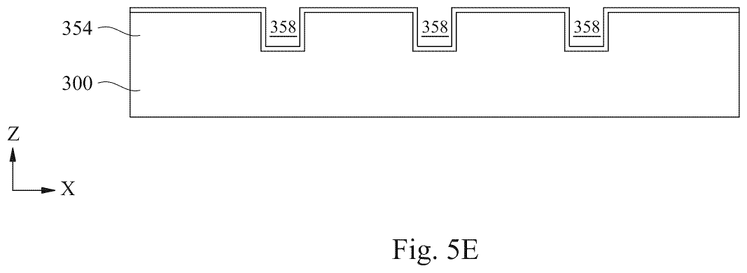

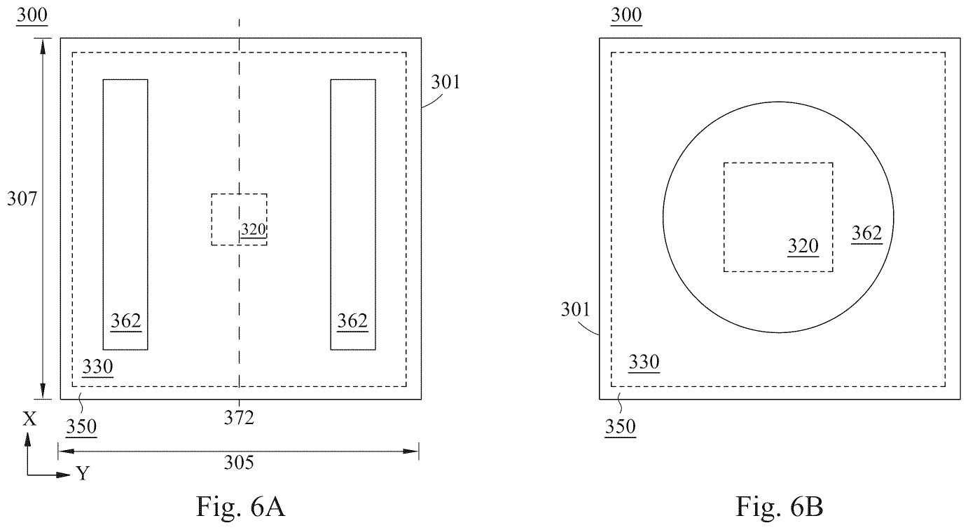

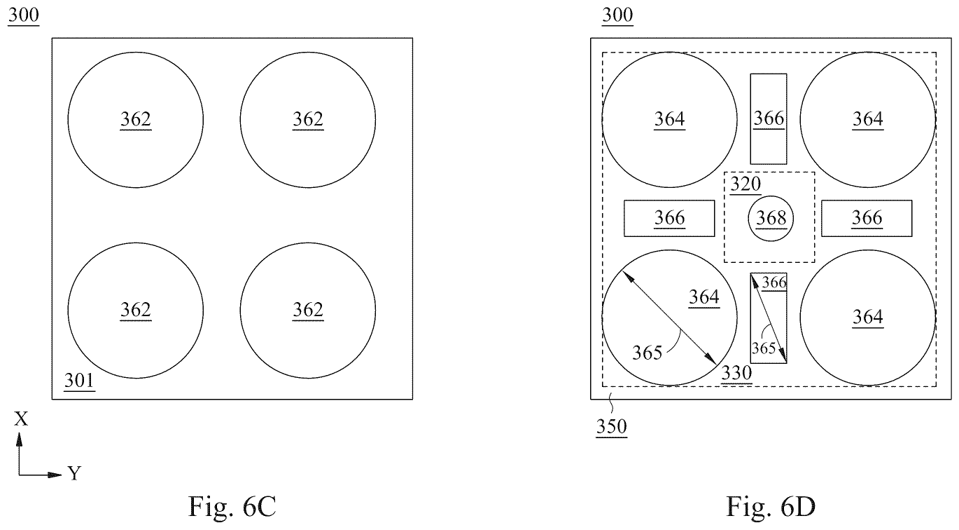

FIGS. 6A-6D are plan views of different embodiments of a carrier wafer 300 of the MEMS cooling device through line B-B of FIG. 4. In these views, the entire carrier wafer is shown, not just the portion in the dashed box 218 of FIG. 5A. As mentioned above, one or more holes 362 are present through the carrier wafer substrate 301. In some embodiments, two or more holes 362 are present through the carrier wafer.

In particular embodiments where two or more holes are present, the holes are located on opposite sides of the carrier wafer. Put another way, if an imaginary line is drawn through the center of the carrier wafer, at least one hole would be entirely on one side of the imaginary line, and at least one hole would be entirely on the other side of the imaginary line. This is illustrated in FIG. 6A, which has two holes 362 and imaginary line 372 is included. In this figure, the holes are rectangular. The central region 320, the intermediate region 330, and the perimeter region 350 are also indicated. These three regions do not have a fixed size, and are somewhat arbitrary labels that may depend on the structures located within them. In the embodiment of FIG. 6B, one circular hole 362 is illustrated. The central region 320 is also larger than that in FIG. 6A.

FIG. 6A also indicates the length 305 and width 307 of the carrier wafer. In particular embodiments, the length 305 is about 30 μm or greater. Similarly, the width 307 is about 30 μm or greater. It is contemplated that the carrier wafer could have maximum dimensions such that only one carrier wafer can be fabricated from a 450-mm wafer, or roughly 318 mm×318 mm. Other ranges and values are also within the scope of the present disclosure.

The embodiment illustrated in FIG. 6C has four holes 362, one located in each quadrant. The embodiment illustrated in FIG. 6D has three types of holes 364, 366, 368. Holes 364, 368 are illustrated with a circular shape, and holes 366 are illustrated with a rectangular shape. It is noted that a hole 368 is located in the central region 320, which is also permitted. In such an embodiment, the thickness of the central region might be the same as that of the intermediate region. Generally, each hole may be of any suitable shape or surface area (when viewed in a plan view), so long as the hole extends through the entire substrate. In particular embodiments, a first hole 364 and a second hole 366 in the plurality of holes have different surface areas or shapes. This can enhance the intensity of liquid flow.

In particular embodiments, each hole may have a diameter 365 of about 5 micrometers (μm) to about 10 μm. With respect to non-circular holes, the term “diameter” refers to the longest length through which liquid may pass through the hole. For example, the diameter of the rectangular hole 366 is its diagonal between opposite corners.

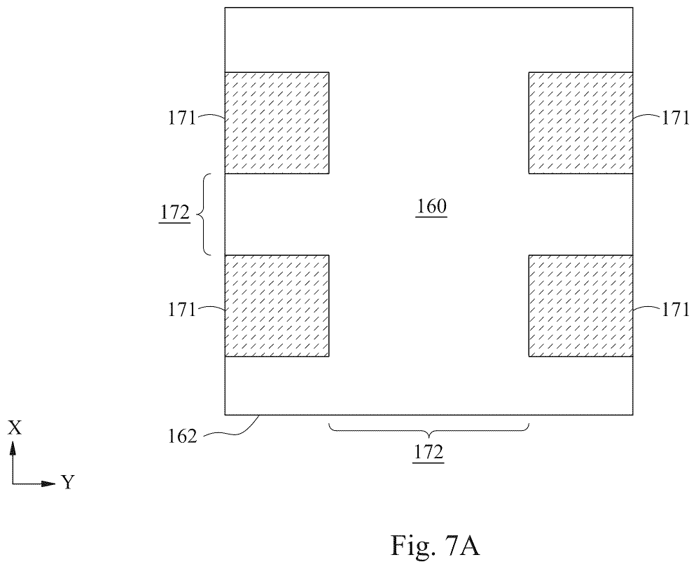

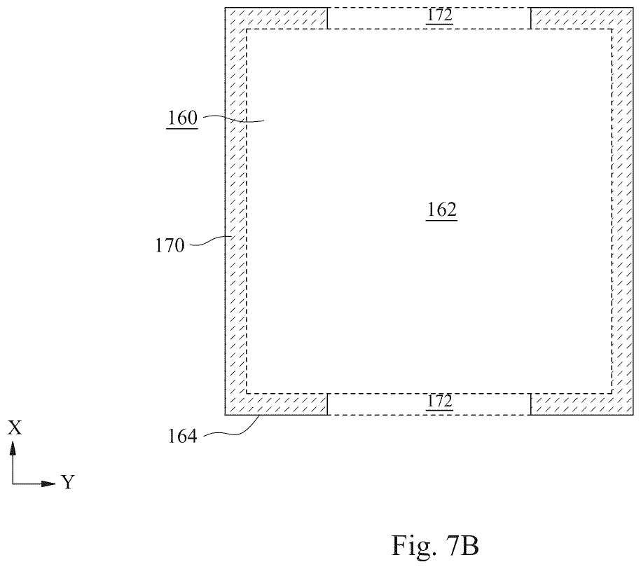

FIG. 7A is a plan view of a first embodiment of an adhesive layer 170 and the heat-generating device 160 through line C-C of FIG. 4. As illustrated here, the adhesive layer 170 is in the form of four spots 171 applied between the surface 162 of the heat-generating device 160 and the second side of the carrier wafer. In addition, the adhesive layer is discontinuous. Put another way, spaces 172 are left so that cooling liquid can flow into an empty volume between the surface 162 of the heat-generating device and the second side of the carrier wafer.

FIG. 7B is a plan view of a second embodiment of an adhesive layer 170 and the heat-generating device 160 through line C-C of FIG. 4. As illustrated here, the adhesive layer 170 is applied along a perimeter 164 of the surface 162 of the heat-generating device 160. Again, the adhesive layer is discontinuous, and spaces 172 are indicated.

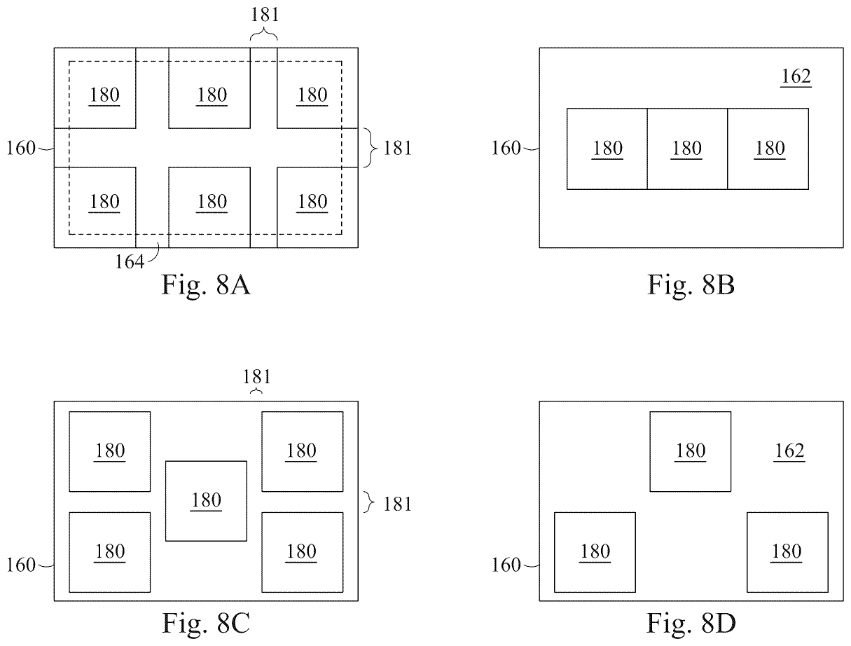

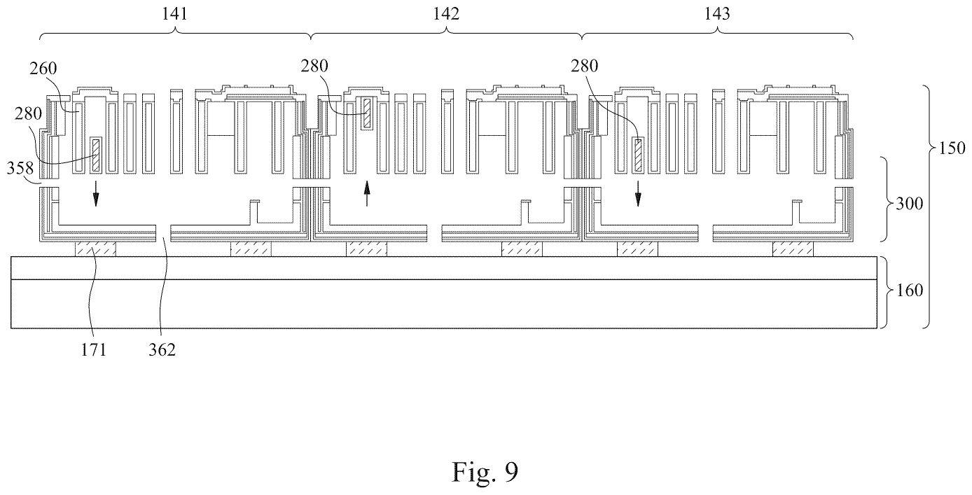

FIGS. 8A-8D are plan views showing different arrangements of MEMS cooling devices 180 on a heat-generating device 160. Generally, a plurality of MEMS cooling devices are placed in any desired locations on the same surface 162 of the heat-generating device, in any desired geometric arrangement. In FIG. 8A, six MEMS cooling devices 180 are placed along the perimeter 164 (indicated with dashed line) in two rows and three columns. The devices are spaced so there is a gap 181 between the cooling devices, which can permit cooling liquid to flow through lateral openings as well. In particular embodiments, the gap has a width of at least 2 micrometers (μm), with a maximum gap of about 30 μm. Other ranges and values are also within the scope of the present disclosure.

In FIG. 8B, three MEMS cooling devices are placed against each other such that there are no gaps between the cooling devices. It is noted that in embodiments where the cooling device includes lateral openings 358, the lateral openings of adjacent cooling devices are desirably aligned with each other to permit liquid to flow between the adjacent devices.

In FIG. 8C, five cooling devices 180 are arranged in a staggered pattern, such that the cooling device in the center column overlaps with but is not in a row with the cooling devices in the left column and the right column. In FIG. 8D, only three cooling devices are present, arranged so that the cooling device in the center column is in a separate row and does not overlap at all with the other cooling devices.

Referring to FIG. 8D, it may be desirable to cover as much of the surface area 165 of the heat-generating device as possible with the MEMS cooling devices. In some embodiments, from about 50% to 100% of the surface area of the heat-generating device is covered by the MEMS cooling devices. Other ranges and values are also within the scope of the present disclosure.

FIG. 9 is a cross-sectional view through another embodiment of a package 150 formed from a heat-generating device 160 with a plurality of MEMS cooling devices attached thereto, in accordance with some embodiments of the present disclosure. As illustrated here, the heat-generating device 160 is a chip on a printed circuit board (PCB). Three MEMS cooling devices 141, 142, 143 are attached through adhesive spots 171. Holes 362 are present through the carrier wafer 300, as are lateral openings 358. As illustrated here, the devices are synchronized so that when the array of second fingers 280 in the left-side device 141 and the right-side device 143 are moving downwards, the array of second fingers 280 in the center device 142 is moving upwards (as indicated by the arrows. The array of first fingers 260 in each device remains motionless. It is noted the internal structure of the MEMS cooling devices only shows the portion of the box 218 in FIG. 5A.

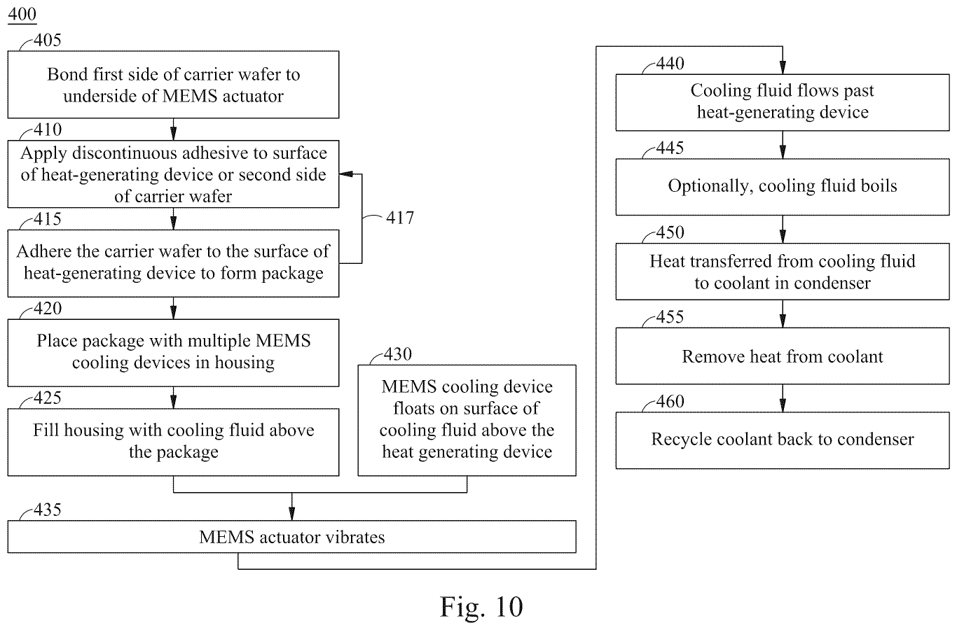

FIG. 10 is a flow chart illustrating a method 400 for making a MEMS cooling device, and for using the MEMS cooling device in a package with a heat-generating device, in accordance with some embodiments. The method is discussed with reference to FIGS. 1A-7B. Other structures may also be concurrently made or formed. It is noted that not all steps described in the flow chart are required, and not all method steps are described in the flow chart.

Initially, referring to FIG. 5B, the method begins with a MEMS actuator 200 and a carrier wafer 300. As indicated in step 405 of FIG. 10, the first side 302 of the carrier wafer is bonded to the underside 224 of the MEMS actuator through bonding layer 174. This may be done by any suitable technique, such as application of adhesive or other suitable material. The bonding layer may be continuous about the perimeter region 350 or may be discontinuous. The combination of the MEMS actuator 200 and the carrier wafer 300 forms a MEMS cooling device 180.

Then, as indicated in step 410 of FIG. 10 and as illustrated in FIGS. 7A-7B, an adhesive 170 is applied to either the second side 304 of the carrier wafer or the surface 162 of the heat-generating device 160. The adhesive may be, for example, a metal glue, a macromolecule, or other liquid-insoluble material. Next, as indicated in step 415 of FIG. 10, the carrier wafer 300 is adhered to the surface of the heat-generating device to form a package 150. These steps are repeated so that multiple MEMS cooling devices are attached to the heat-generating device, as indicated by arrow 417.

Then, as indicated in step 420 of FIG. 10, the package is placed in the housing 102 of FIG. 1B or FIG. 2. In step 425 of FIG. 10, the housing 102 is filled with a cooling liquid, such as a dielectric liquid, above the level of the package 150. These steps may be reversed as desired. Alternatively or in addition, in step 430 of FIG. 10 and as illustrated in FIG. 1B, a MEMS cooling device 180 may float at or near the surface 105 of the cooling liquid, above the packages 150.

In operation, the heat-generating devices create heat energy that is absorbed by the cooling fluid/liquid. This may cause currents within the cooling liquid, or the formation of bubbles. As indicated in step 435 of FIG. 10, the MEMS actuator vibrates. This vibration may occur naturally due to liquid flow or other physical phenomena, or an insulated electrical cable may be connected to the MEMS actuator to induce vibration. Vortices can be formed around the center of the actuator, which also increases the rate of fluid flow past the heat-generating device.

Referring to FIG. 5B and FIG. 9, during operation, in particular embodiments, in a given MEMS cooling device, the second fingers 280 vibrate vertically (i.e. up-and-down in the Z-axis) relative to the first fingers 260. For example, the first fingers 260 can remain still and not vibrate at all. As previously mentioned, the second fingers are shorter than the first fingers, and so they have extra space in which to vibrate. In particular embodiments, where a plurality of MEMS cooling devices are present on the same heat-generating device, the second fingers of at least one cooling device will vibrate in the opposite direction from the second fingers of at least one different cooling device. This enhances the flow of the cooling liquid.

Due to the vibration, as indicated in step 440 of FIG. 10, cooling fluid flows past the heat-generating device at a higher rate (e.g. gallons/minute) compared to the situation in which the MEMS actuator is not present. The bubbles or liquid currents will pass through the holes of the carrier wafer and are pulled through the MEMS actuator.

If the system is a dual-phase system as illustrated in FIG. 1A, the cooling fluid boils, as indicated in optional step 445 of FIG. 10. As indicated in step 450, heat is transferred from the cooling fluid to the coolant in the condenser coil 108. Then, as indicated in step 455 of FIG. 10, heat is removed from the coolant in the heat exchanger 109. Finally, as indicated in step 460, the coolant is recycled back to the condenser coil 108.

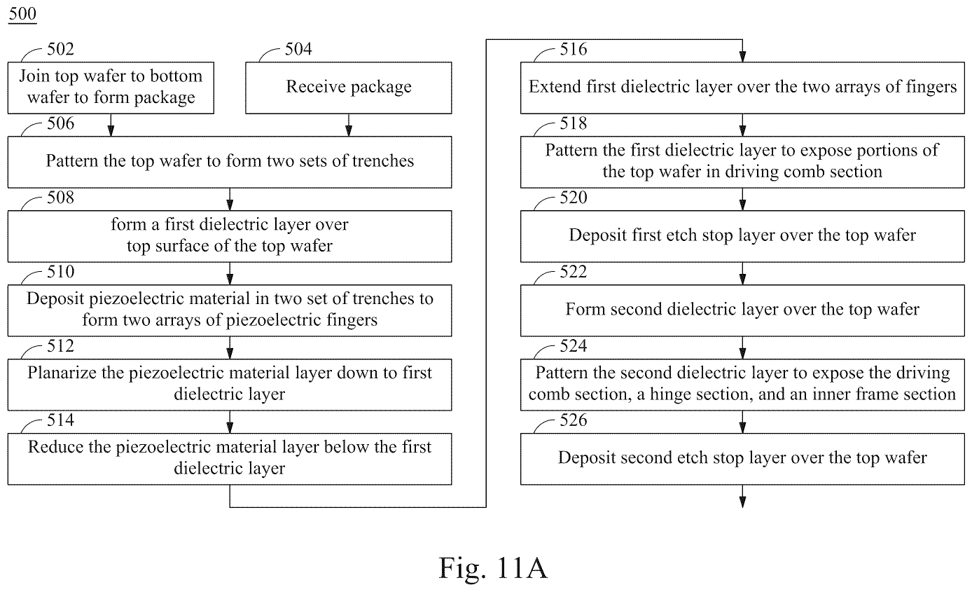

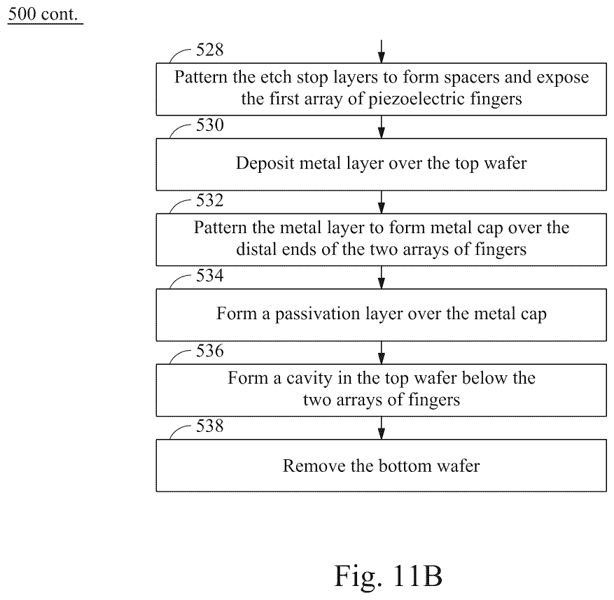

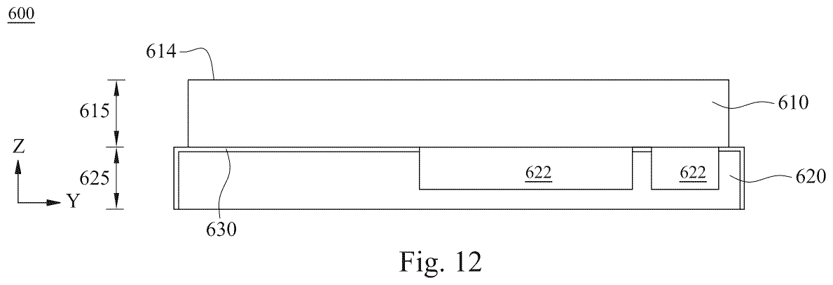

FIG. 11A and FIG. 11B together form a flow chart illustrating a first method 500 for making a MEMS actuator, in accordance with some embodiments. Some steps of the method are also illustrated in FIGS. 12-29B. These figures provide different views for better understanding. While the method steps are discussed below in terms of forming a single micromechanical arm array with a small number of fingers, such discussion should also be broadly construed as applying to the concurrent formation of multiple micromechanical arm arrays located in a single driving comb section, and also to the formation of many fingers, and the formation of the entire actuator and multiple actuators. These figures do not show the formation of the entire actuator, only the driving comb section.

Initially, in step 502 of FIG. 11A and as illustrated in FIG. 12, a top wafer 610 is joined to a bottom wafer 620 to form a package 600. Alternatively, as shown in step 504 of FIG. 11A, a package is received.

The top wafer 610 and the bottom wafer 620 may independently be, for example, a wafer made of a semiconducting material. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the two wafers are made of silicon.

The top wafer includes a top surface 614 which also acts as the top surface of the package. Generally, the top wafer 610 has a relatively lower thickness 615 (for example in the range of about 200 μm) which results in the top wafer being very flexible and thus difficult to process by itself. The bottom wafer 620 has a relatively higher thickness 625 (for example in the range of about 500 μm) that increases the overall thickness of the package and thus provides mechanical stability during processing, and can also aid in electrical isolation (if desired). Two cavities 622 are already present within the bottom wafer 620. The bonding layer 630 may be formed by fusion bonding, for example, by a heating and/or pressing process without any additional layers. As another example, both wafers may have a dielectric layer on appropriate surfaces which are then heated. The two wafers are then pressed together to form the bonding layer.

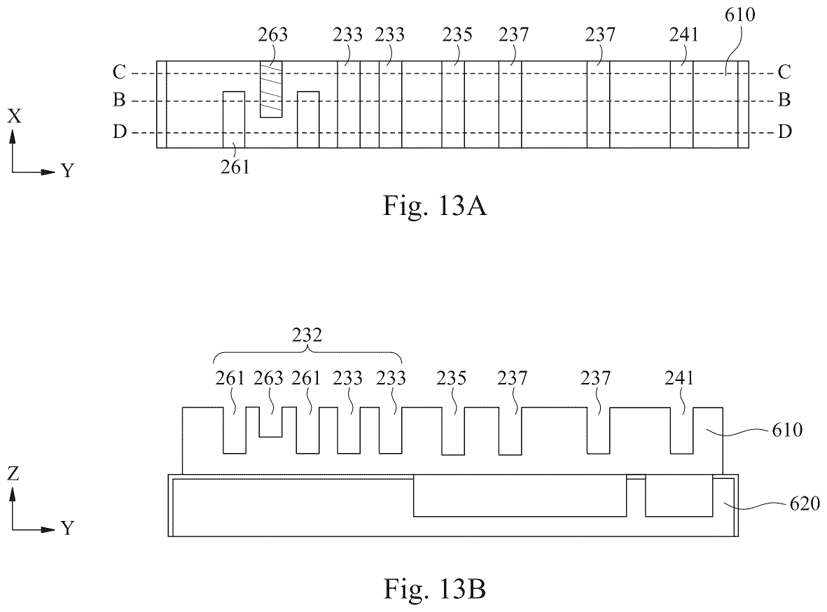

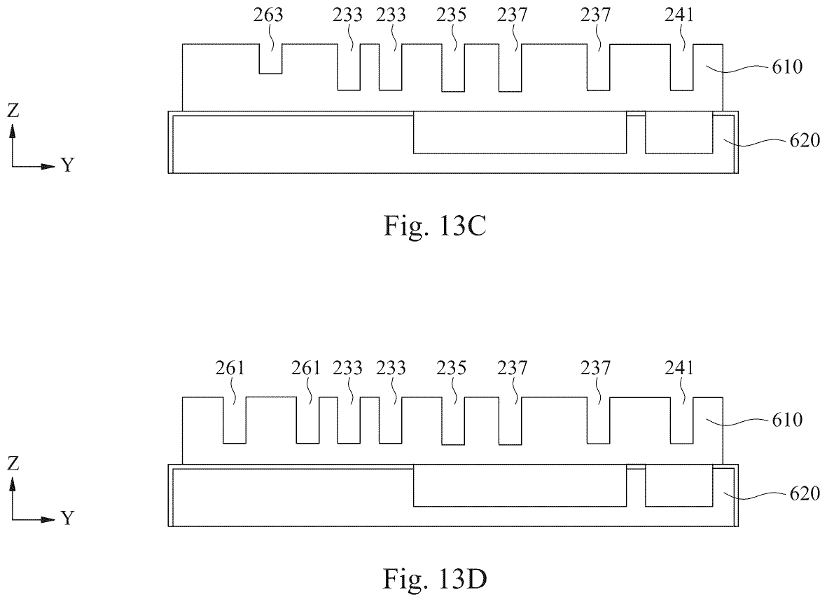

Next, in step 506 of FIG. 11A and as illustrated in FIGS. 13A-13D, the top wafer 610 is patterned to form two different sets of trenches 261, 263 which will correspond to the two different arrays of fingers. The trenches 261, 263 are formed within the driving comb section 232. Additional trenches 233 are also formed in the driving comb section. Additional trenches 235, 237, 241 are also formed in the top wafer in locations which will correspond to the hinge section, the inner frame section, the spring section, and the outer frame section.

FIG. 13A is a plan view of the package after this patterning/etching step. As illustrated here, the two different sets of trenches 261, 263 are visible. It is noted that a “set” of trenches may be as few as one trench. The different depths of the trenches 261, 263 are indicated with different shading. FIG. 13B is a side cross-sectional view of the package through line B-B of FIG. 13A. This cross-section passes through the location where the distal ends of the fingers will be formed. The different heights of the two sets of fingers (relative to top surface 614) is indicated by trench 263 being formed upon a stand 616.

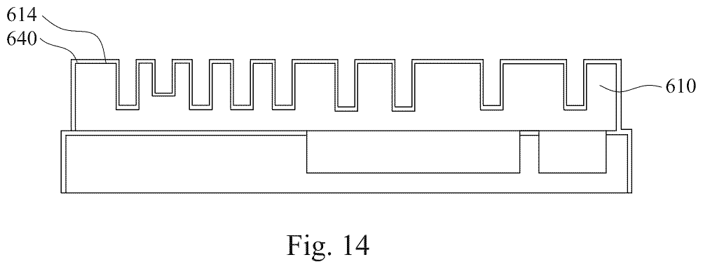

FIG. 13C is a side cross-sectional view of the package through line C-C of FIG. 13A. In this cross-section, only the trenches 263 for the second array of fingers are visible. FIG. 13D is a side cross-sectional view of the package through line D-D of FIG. 13A. In this cross-section, only the trenches 261 for the first array of fingers are visible. It is noted that the cross-sectional views of FIGS. 14-31B are also through line B-B of FIG. 13A unless otherwise indicated.

Next, in step 508 of FIG. 11A and as illustrated in FIG. 14, a first dielectric layer 640 is formed on the exposed surfaces of the top wafer 610, including the top surface 614. In particular embodiments, the first dielectric layer is made of silicon dioxide (SiO₂), which can be formed by thermal oxidation of the silicon wafer.

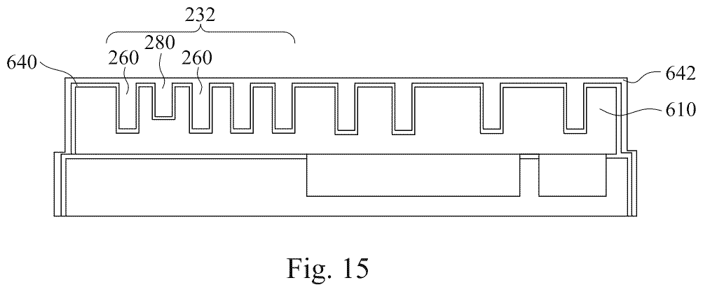

Next, in step 510 of FIG. 11A and as illustrated in FIG. 15, a piezoelectric material 642 is deposited into the trenches 261, 263 to form two arrays of piezoelectric fingers 260, 280. Referring back to FIG. 5C, the first arm 278 and the second arm 298 are also formed in this step. The deposition may be performed using chemical vapor deposition (CVD), physical vapor deposition (PVD), atomic layer deposition (ALD), or other suitable methods. Examples of suitable piezoelectric materials may include barium titanate (BaTiO₃, BTO), lead titanate (PbTiO₃), lead zirconium titanate (PZT), or potassium sodium niobate (KNN).

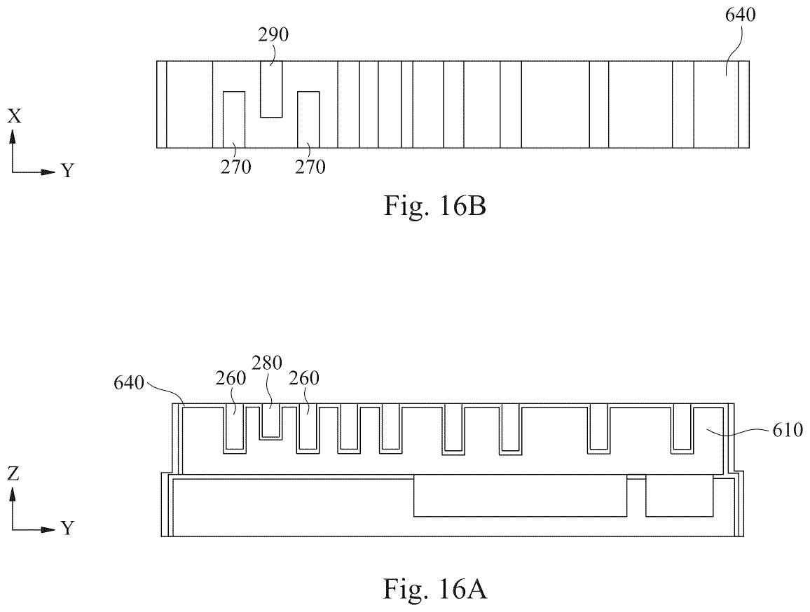

In step 512 of FIG. 11A and as illustrated in FIG. 16A and FIG. 16B, the piezoelectric material layer is planarized down to the first dielectric layer 640. The first dielectric layer acts as an etch stop layer for this step. It can be seen in FIG. 16B that the distal ends 270, 290 of the two arrays of fingers are interposed between each other.

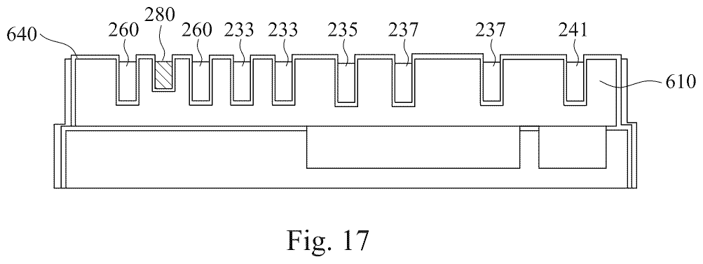

In step 514 of FIG. 11A and as illustrated in FIG. 17, the level of the piezoelectric material 642 is reduced to below the level of the first dielectric layer 640. The level of piezoelectric material is also reduced in the other trenches 233, 235, 237, 241 in the top wafer. This may be done by selective etching of the piezoelectric material. It is noted that fingers 260, 280 are made of the same material, but will be illustrated with different textures to distinguish them.

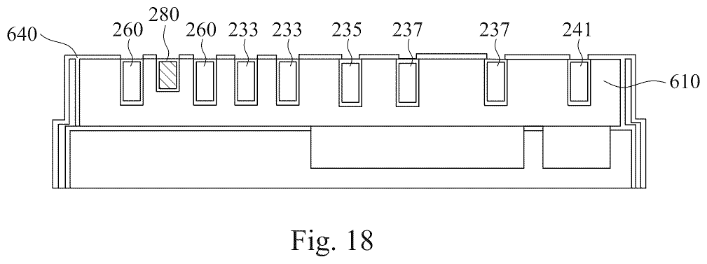

Subsequently, in step 516 of FIG. 11A and as illustrated in FIG. 18, a dielectric layer is formed upon the exposed surfaces of the piezoelectric material 642. This step may be considered as adding to the first dielectric layer 640. This may be done using suitable methods. The addition to the first dielectric layer also occurs on the other trenches 233, 235, 237, 241 in the top wafer 610.

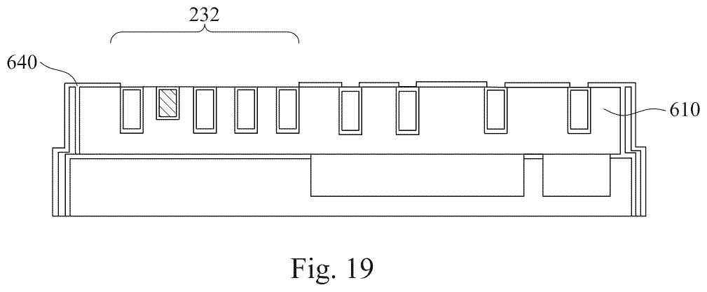

Then, in step 518 of FIG. 11A and as illustrated in FIG. 19, the first dielectric layer 640 is patterned to expose portions of the top wafer 610 within the driving comb section 232. As will be seen later, this is done to permit silicon to be removed later. Portions of the first dielectric layer are removed from the driving comb section to expose the top wafer.

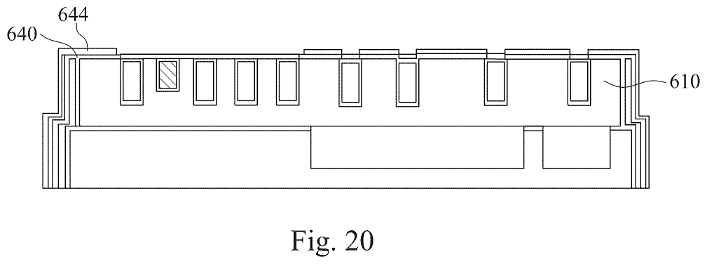

Next, in step 520 of FIG. 11A and as illustrated in FIG. 20, a first etch stop layer 644 is deposited over the top wafer. The deposition may be performed using CVD, PVD, or other suitable methods. The first etch stop layer may be made of any material that is different from the material of the first dielectric layer 640, such as a different dielectric material or an electrically conductive material. In particular embodiments, the first stop etch layer is made of polysilicon.

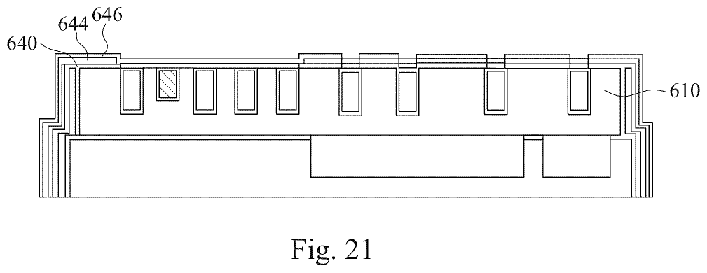

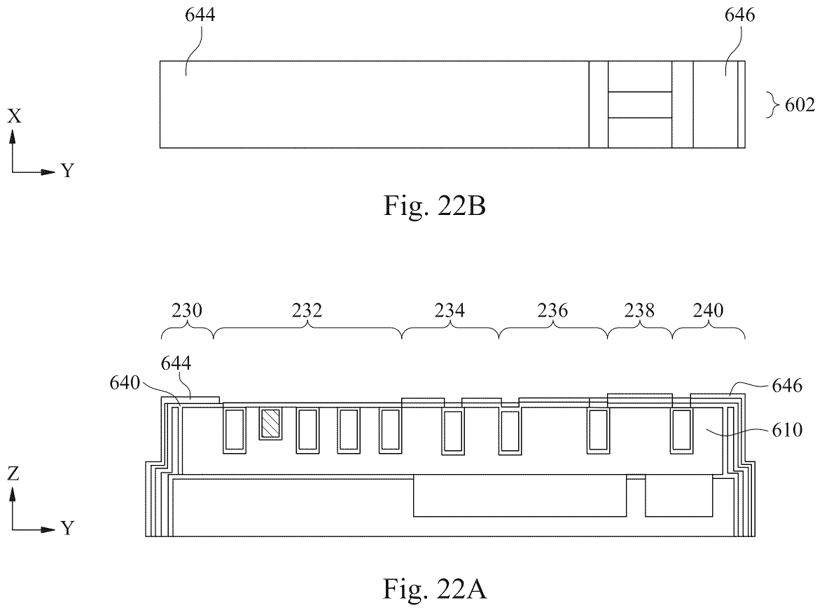

In step 522 of FIG. 11A and as illustrated in FIG. 21, a second dielectric layer 646 is formed over the first etch stop layer 644. This may be done by deposition such as CVD, PVD, or other suitable methods. Then, in step 524 of FIG. 11A and as illustrated in FIG. 22A and FIG. 22B, the second dielectric layer is patterned to expose the driving comb section 232, the hinge section 234, and a portion of the inner frame section 236. Put another way, the second dielectric layer is removed from these three sections. As a result, the second dielectric layer 646 remains upon a portion of the inner frame section 236, the spring section 238, and the outer frame section 240. In the spring section 238, the second dielectric layer 646 is present across a central section 602 aligned with the distal ends of the fingers 260, 280. The first etch stop layer 644 is exposed where the second dielectric layer has been removed. Generally, the first dielectric layer 640 and the second dielectric layer 646 are made of the same material.

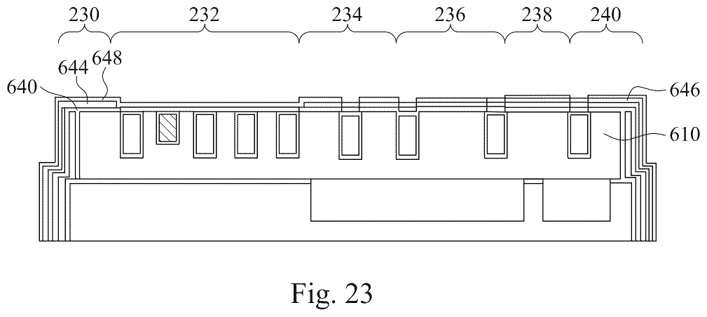

Next, in step 526 of FIG. 11A and as illustrated in FIG. 23, a second etch stop layer 648 is deposited over the top wafer. The deposition may be performed using CVD, PVD, or other suitable methods. In particular embodiments, the second etch stop layer is made of the same material as the first etch stop layer 644. As illustrated here, then, there are several locations in the anchor arm section 230, the driving comb section 232, the hinge section 234, and the inner frame section 236 where the two etch stop layers 644, 648 directly contact each other.

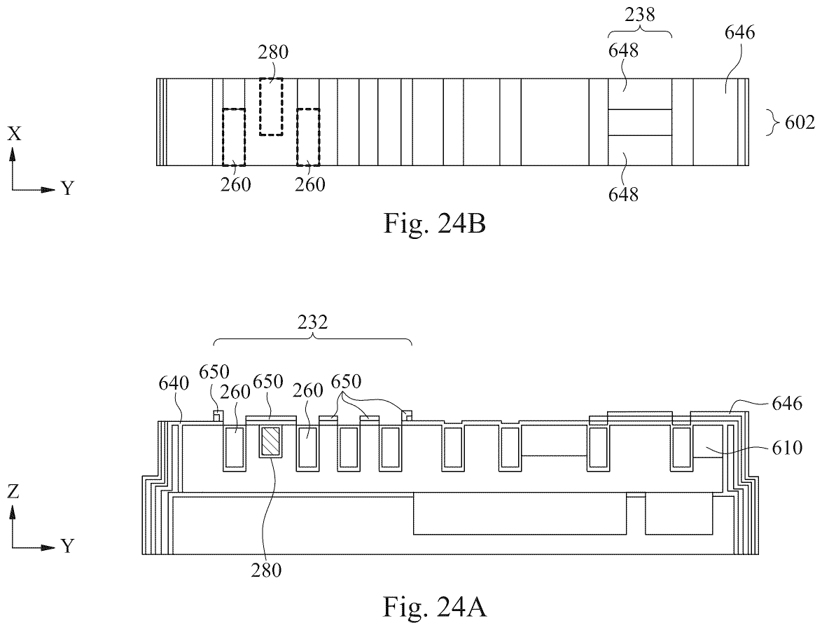

Then, in step 528 of FIG. 11B and as illustrated in FIG. 24A and FIG. 24B, the two etch stop layers are patterned to expose the first array of fingers 260 within the driving comb section. The second array of fingers 280 are still covered by spacers 650 formed from the two etch stop layers. Spacers 650 are also present over the portions of the top wafer 610 between the arrays of fingers 260, 280 and the trenches 233 in the driving comb section 232. Spacers 650 are also present upon the first dielectric layer 640 adjacent the driving comb section 232. As seen in FIG. 24B, the second etch stop layer 648 is also visible in the spring section 238 to either side of the central section 602 aligned with the distal ends of the fingers 260, 280 (shown in dashed line).

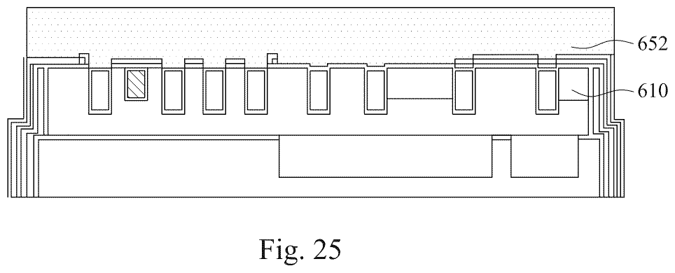

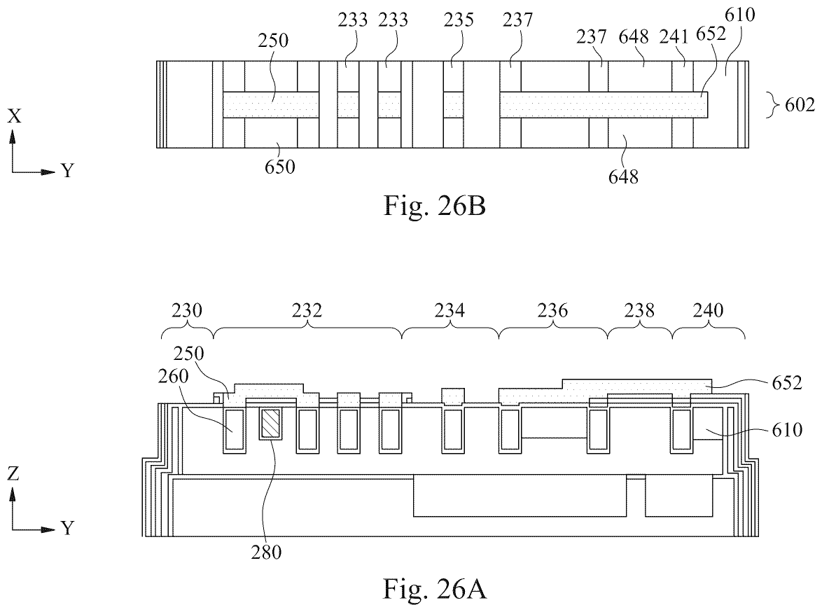

In step 530 of FIG. 11B and as illustrated in FIG. 25, a metal layer 652 is deposited over the top wafer 610. The deposition may be performed using CVD, PVD, or other suitable methods. Then, in step 532 of FIG. 11B and as illustrated in FIG. 26A and FIG. 26B, the metal layer is patterned to form a metal cap 250 over the distal ends of the two arrays of fingers 260, 280. The metal layer is also patterned to remain in a central section 602 upon the other trenches 233, 235, 237, 241 in the driving comb section 232, the hinge section 234, the inner frame section 236, the spring section 238, and the outer frame section 240. It is noted that the metal layer 652 has two different heights; this can be obtained through two consecutive mask/etch steps. It should also be noted that the spacers 650 in the driving comb section 232 are exposed from above, as seen in FIG. 26B.

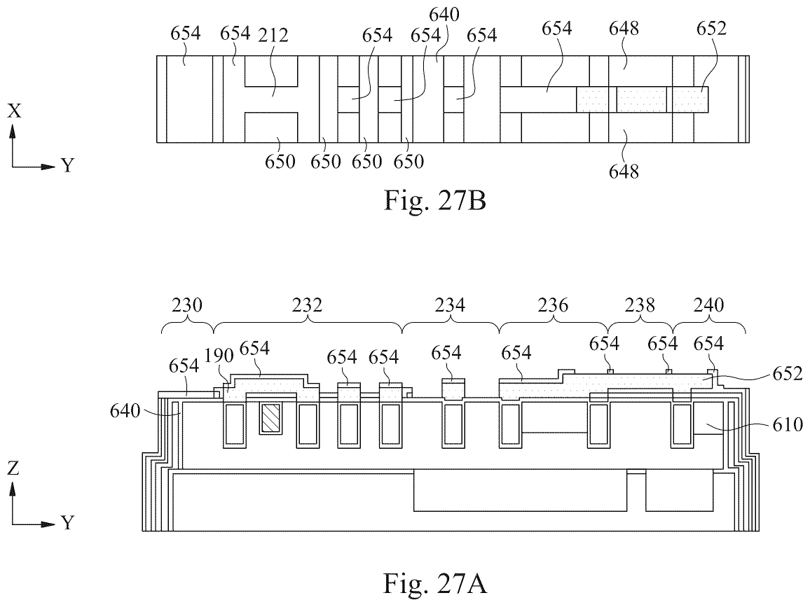

Next, in step 534 of FIG. 11B and as illustrated in FIG. 27A and FIG. 27B, a passivation layer 654 is formed upon the metal cap 250. The passivation layer 654 is also formed upon the metal layer 652 in the driving comb section 232, the hinge section 234, the inner frame section 236, the spring section 238, and the outer frame section 240. The passivation layer may be formed by deposition of a third dielectric layer and patterning to remove the third dielectric layer from undesired locations. Although not visible, the passivation layer is also present upon the sides of the metal cap 250 and the metal layer 652.

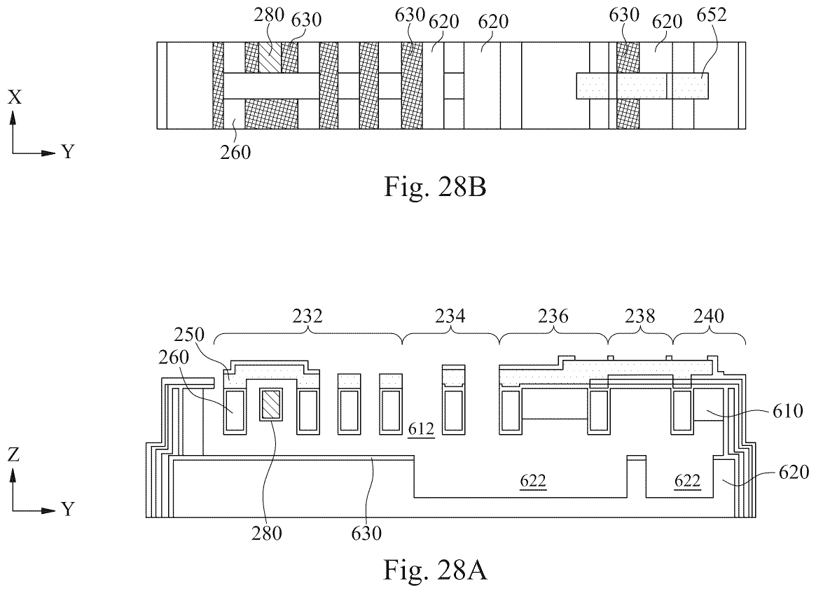

Then, in step 536 of FIG. 11B and as illustrated in FIG. 28A and FIG. 28B, a cavity 612 is formed in the top wafer 610 below the two arrays of fingers 260, 280. This may be done, for example, by patterning the top wafer, then etching away the exposed vertical spacers 650 and the first dielectric layer 640 (see FIG. 27A and FIG. 27B) below the vertical spacers using a dry etch process, then etching the silicon using a wet etch process. In this regard, the wet etch process can be controlled by timing. After the wet etchant etches through the top wafer, the cavities 622 in the bottom wafer provide a volume to collect and neutralize the wet etchant. The material of the top wafer is also etched in the hinge section 234 and the spring section 238. Some undercutting may occur, which is acceptable. When viewed from the top, the bonding layer 630 and portions of the bottom wafer 620 are also visible.

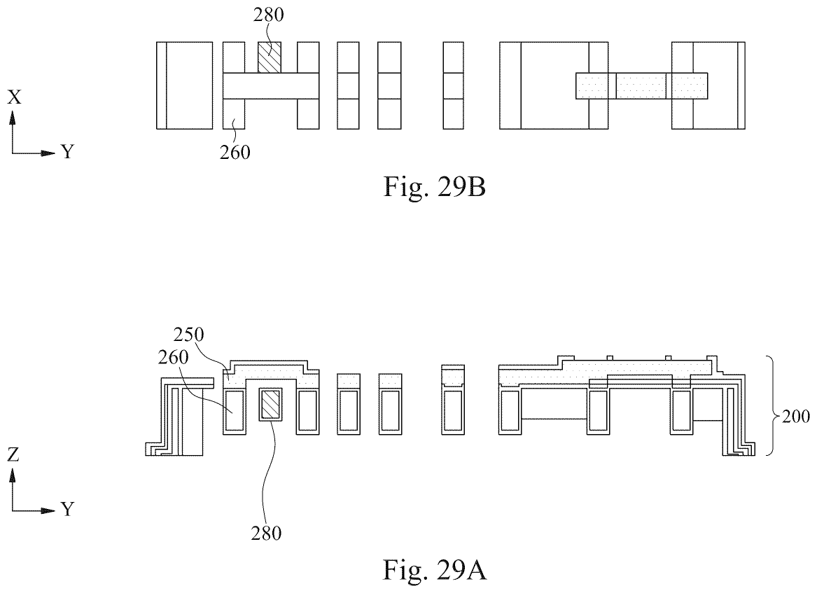

Next, in step 538 of FIG. 11B, the bottom wafer 620 is subsequently removed or separated from the top wafer 610. The resulting structure, a MEMS actuator 200, is illustrated in FIG. 29A and FIG. 29B. The MEMS actuator will subsequently be joined to a patterned carrier wafer.

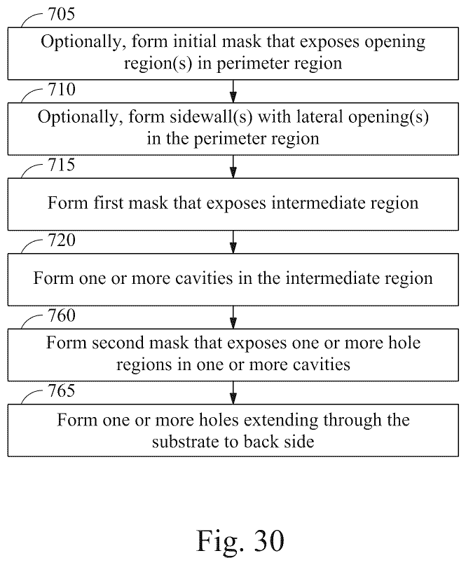

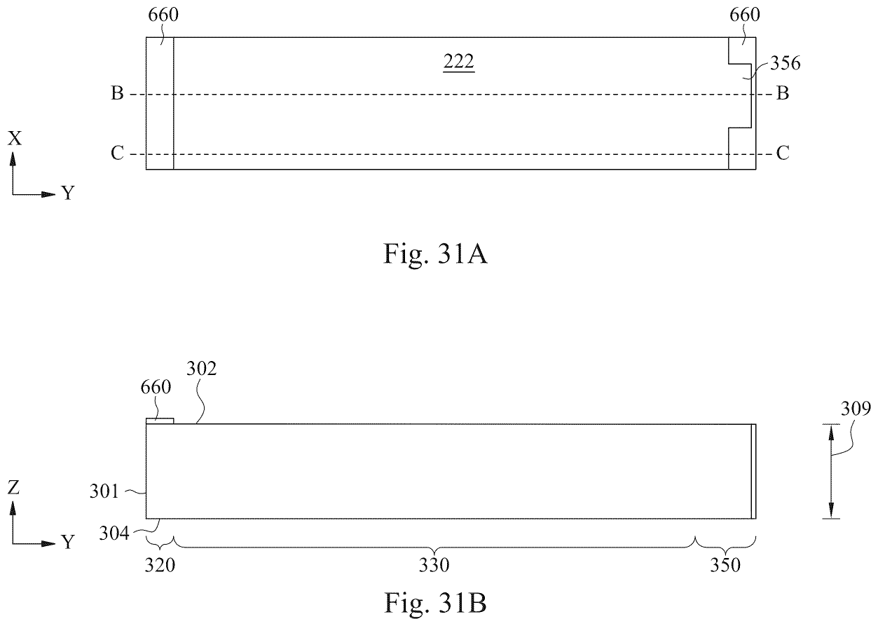

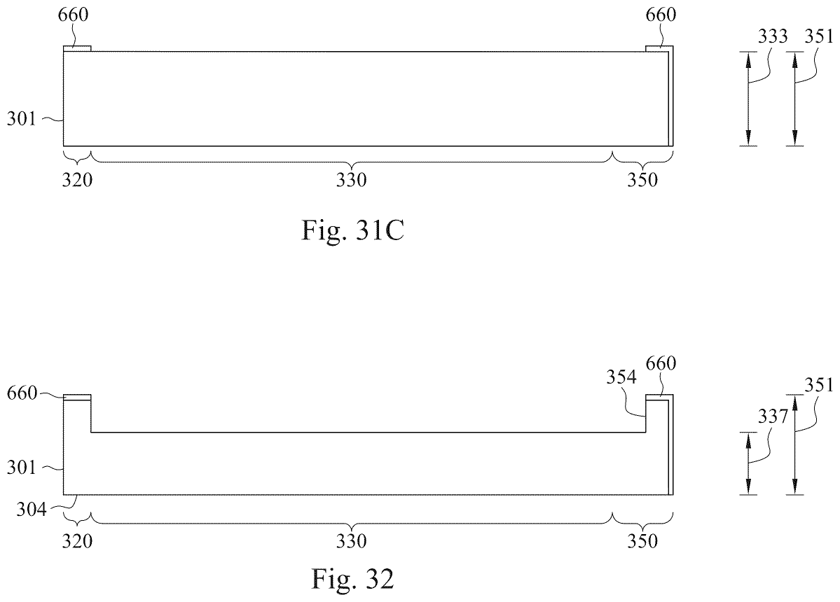

FIG. 30 is a flow chart illustrating a first method 700 for making a carrier wafer through which liquid can flow, in accordance with some embodiments. Some steps of the method are also illustrated in FIGS. 31A-36. These figures provide different views for better understanding. While the method steps are discussed below in terms of forming a single carrier wafer, such discussion should also be broadly construed as applying to the concurrent formation of multiple carrier wafers. These figures do not show the formation of the entire carrier wafer, but are illustrated for the portion in the dashed box 218 of FIG. 5A. Other structures may also be concurrently formed. It is noted that not all steps described in the flow chart are required, and not all method steps are described in the flow chart.

Referring first to FIG. 31A and FIG. 31B, the method begins with a substrate 301. The base substrate may be, for example, a wafer made of a semiconducting material, such as previously described. In particular embodiments, the substrate is silicon. The substrate 301 has a first side/front side/upper surface 302 and a second side/back side/lower surface 304, and has an initial thickness 309 between these two surfaces.

If it is desired to form openings 358 as illustrated in the embodiment of FIG. 5B and FIG. 5E, then as indicated in optional step 705 of FIG. 30 and as illustrated in FIGS. 31A-31C, an initial mask 660 is formed upon the first side 302 of the substrate. One or more opening regions 356 are exposed in the perimeter region 350 of the substrate 301. The intermediate region 330 is also exposed. As illustrated here, the central region 320 is not exposed, but this is not required (i.e. some portions or all of the central region can be exposed too). The absence of the initial mask in the opening region 356 of the perimeter region is seen in FIG. 31B. Also indicated in FIG. 31C are an initial thickness 333 of the intermediate region 330 and an initial thickness 351 of the perimeter region 350, which are currently equal. The presence of the initial mask 660 in the rest of the perimeter region 350 is seen in FIG. 31C.

Then, as indicated in optional step 710 of FIG. 30 and as illustrated in FIG. 32, a sidewall 354 with one or more openings (not visible) is formed in the perimeter region 350. An intermediate thickness 337 of the intermediate region is less than the initial thickness 351 of the perimeter region (measured relative to the second side 304 of the substrate). FIG. 5E shows an X-axis view where three openings 358 are formed. This may be done by etching. The initial mask is then removed.

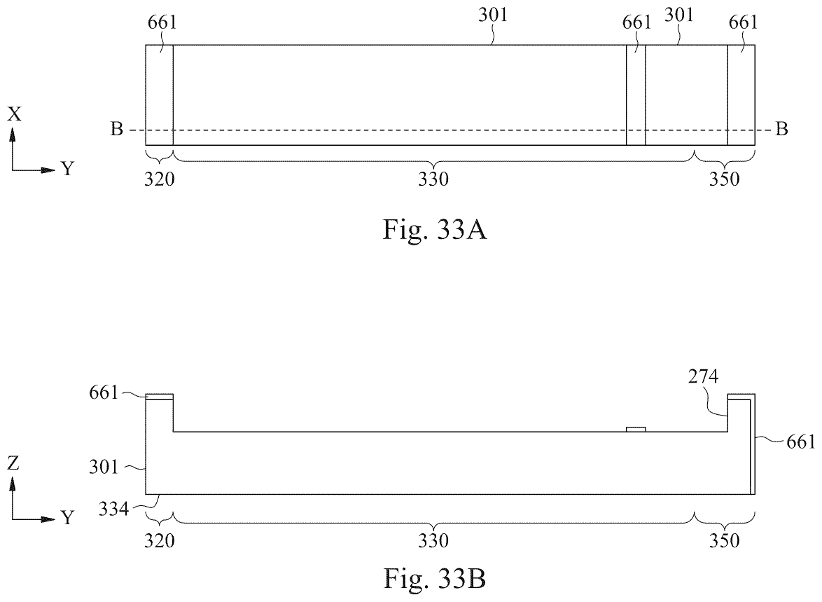

Next, as indicated in step 715 of FIG. 30 and as illustrated in FIG. 33A and FIG. 33B, a first mask 661 is formed upon the first side of the substrate. A portion of the intermediate region 330 is exposed. As illustrated here, the central region 320 is not exposed, but this is not required (i.e. some portions or all of the central region can be exposed too). Similarly, a portion of the perimeter region 350 is not exposed.

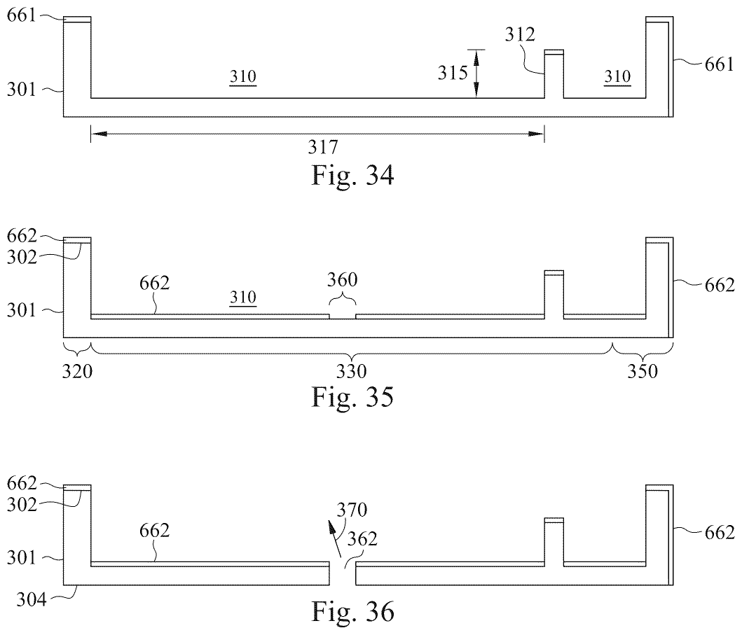

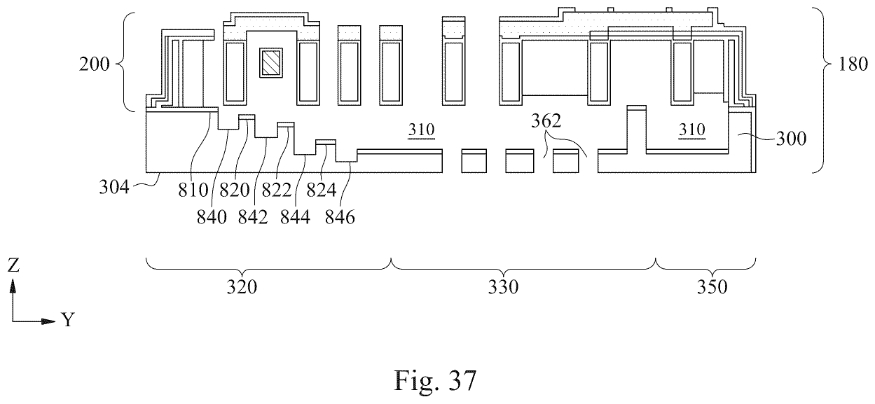

Continuing, as indicated in step 720 of FIG. 30 and as illustrated in FIG. 34, one or more cavities 310 are formed in the intermediate region 330. This may be done by etching through the first mask 661. The resulting structure is shown in FIG. 37, which illustrates two cavities 310 separated from each other by a sidewall 312.

In particular embodiments, at least one cavity 310 has a depth 315 of about 10 μm or greater. At least one cavity has a length 317 of about 20 μm or greater. Other ranges and values are also within the scope of the present disclosure.

Subsequently, as indicated in step 760 of FIG. 30 and as illustrated in FIG. 35, a second mask 662 is formed upon the first side 302 of the substrate. One or more hole regions 360 are exposed in the intermediate region 330. One hole region is illustrated here. As shown here, the hole regions are illustrated as being in one cavity 310, but they may be present in other cavities as well.

Finally, as indicated in step 765 of FIG. 30 and as illustrated in FIG. 36, one or more holes 362 are formed that extend entirely through the substrate 301. Put another way, a fluid passageway 370 thus extends entirely through the carrier wafer 300 from the first side 302 to the second side 304. Here, one hole is illustrated. This may be done by etching through the second mask 662. The resulting structure corresponds to the carrier wafer illustrated in FIG. 5B. It is noted that if the second mask 662 is a hard mask instead of photoresist, then the second mask does not need to be removed before the carrier wafer is attached to the MEMS actuator.

FIG. 37 is a side cross-sectional view of another illustrative embodiment of a MEMS cooling device 180 which can be attached to a heat-generating device, in accordance with some embodiments of the present disclosure. Here, the central region 320 of the carrier wafer 300 includes a plurality of steps 810 extending downwards towards the intermediate region 330. In this illustration, four steps 810, 820, 822, 824 are present. In some particular embodiments, there are 1 to 4 steps, although other values are within the scope of the present disclosure. The top step 810 is bonded to the MEMS actuator 200. The other three steps 820, 822, 824 are located between trenches 840, 842, 844, 846. Two cavities 310 are illustrated, one of which may be considered as extending into the central region 320 as well. Four holes 362 that extend to the second side 304 of the substrate are also illustrated. The presence of the steps may aid in changing the direction of liquid flow and/or increasing the rate of liquid flow through the carrier wafer. This can also create turbulence in the liquid flow.

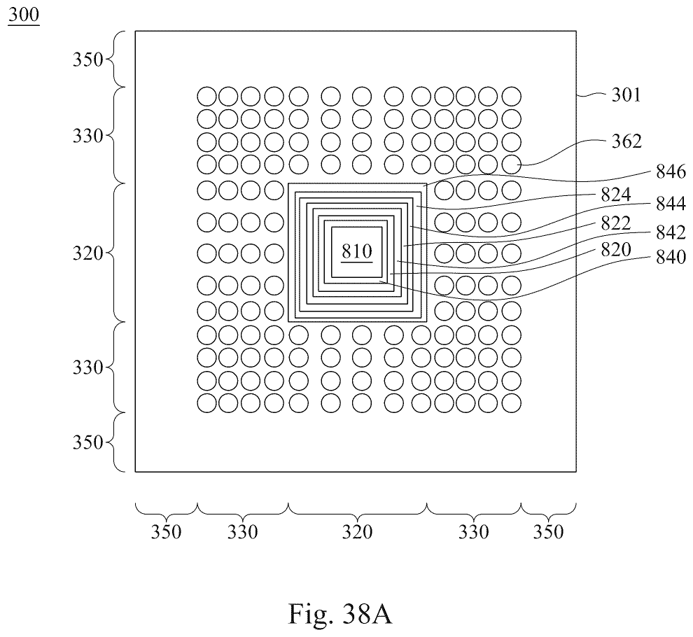

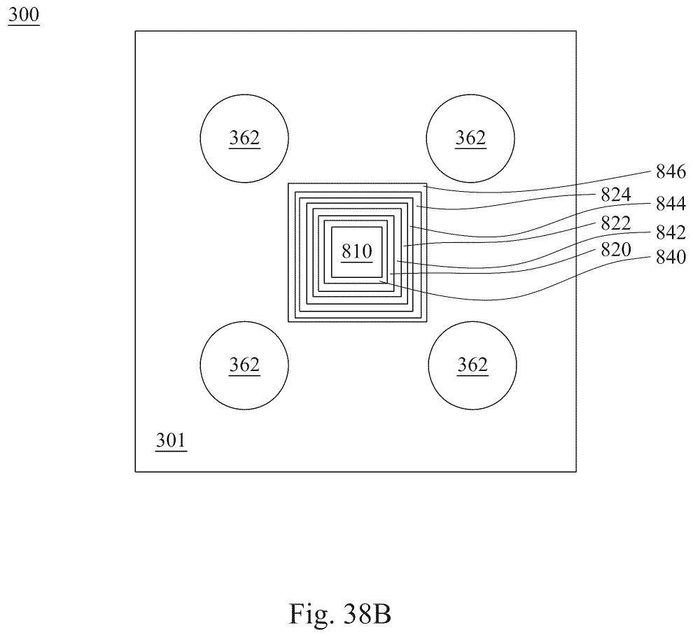

FIG. 38A is a plan view of the entire carrier wafer 300 of FIG. 37 (i.e. not corresponding to the partial view of FIG. 37). The four steps 810, 820, 822, 824 are seen as having a rectangular shape, along with the trenches 840, 842, 844, 846. This particular embodiment is illustrated with 84 holes 362, and reflects the variety of designs that can be made in the carrier wafer. FIG. 38B is a plan view of another embodiment of the carrier wafer 300. Here, the steps 810 are present, along with four relatively large holes 362 in the carrier wafer 300.

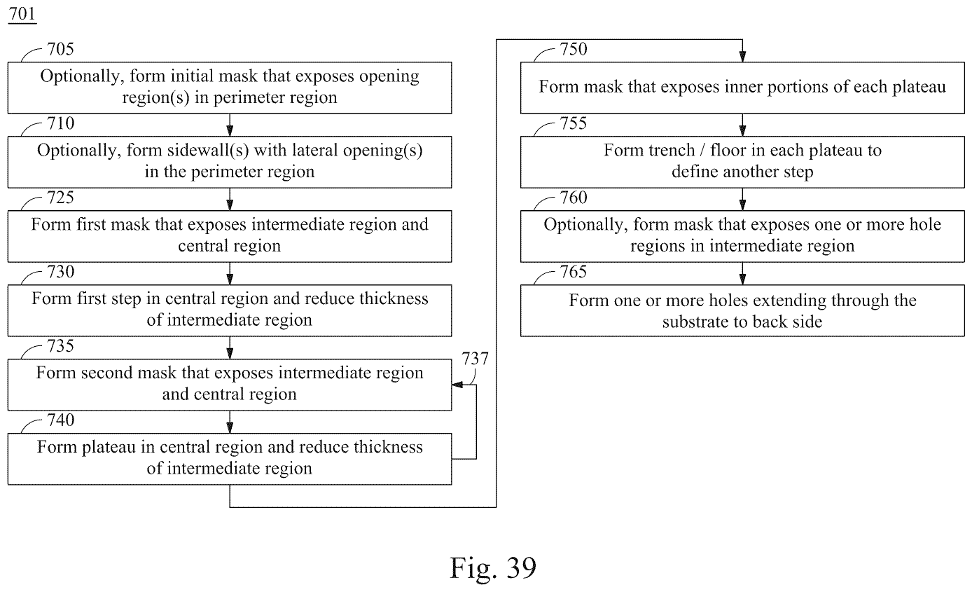

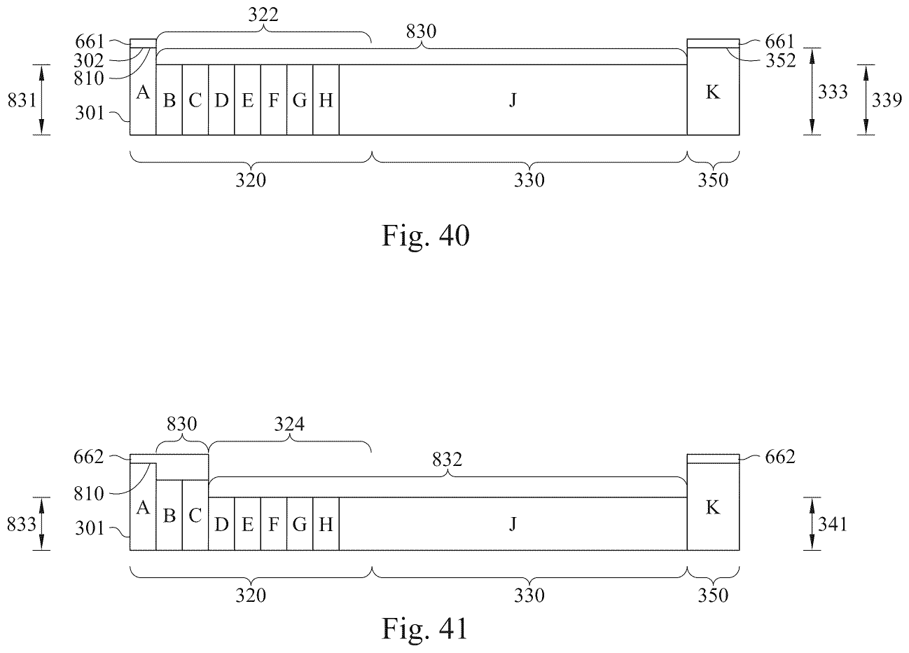

FIG. 39 is a flow chart illustrating a second method 701 for making a carrier wafer through which liquid can flow, in accordance with some embodiments. Some steps of the method are also illustrated in FIGS. 40-45. In particular, the carrier wafer is patterned to form a plurality of steps in the central region. These figures provide different views for better understanding. While the method steps are discussed below in terms of forming a single carrier wafer, such discussion should also be broadly construed as applying to the concurrent formation of multiple carrier wafers. These figures do not show the formation of the entire carrier wafer, but are illustrated for the portion in the dashed box 218 of FIG. 5A and in FIG. 37. Other structures may also be concurrently formed. It is noted that not all steps described in the flow chart are required, and not all method steps are described in the flow chart.

Initially, if it is desired to form openings 358 as illustrated in the embodiment of FIG. 5B and FIG. 5E, then as indicated in optional step 705 of FIG. 39, an initial mask 660 is formed upon the first side 302 of the substrate. Then, as indicated in optional step 710 of FIG. 39, a sidewall 354 with one or more openings 358 is formed in the perimeter region 350. These steps were previously illustrated, and are not repeated here.

As indicated in step 725 of FIG. 39 and as illustrated in FIG. 40, a first mask 661 is formed over the first side 302 of the substrate 301. The intermediate region 330 and a first portion 322 of the central region 320 is exposed. The perimeter region 350 is covered. For reference purposes, the substrate is labeled as having columns A, B, C, D, E, F, G, H, J, and K. Columns A-H are in the central region, column J is in the intermediate region, and column K is in the perimeter region.

Then, as indicated in step 730 of FIG. 39, a top step or first step 810 is formed in the central region 320, along with a first plateau 830. This may be done by etching. The first plateau 830 is located below the first step 810, and is adjacent to the first step 810. Here, column A corresponds to the top step, and columns B through H together form the first plateau. The thickness of the intermediate region 330 has been reduced from an initial thickness 333 to a first intermediate thickness 339. The height 831 of the first plateau 830 corresponds to the first intermediate thickness 339 of the intermediate region. In particular embodiments, the top step 810 is level with the upper surface 352 of the perimeter region 350.

Next, as indicated in step 735 of FIG. 39 and as illustrated in FIG. 41, a second mask 662 is formed over the first side of the substrate 301. The intermediate region 330 and a second portion 324 of the central region 320 is exposed. The second portion surrounds the first portion 322 (in a plan view). Then, as indicated in step 740 of FIG. 39, a second plateau 832 is formed in the central region. This may be done by etching. The second plateau 832 is located below the first plateau 830, and is adjacent to the first plateau 830. Here, the first plateau is now formed by columns B and C, and columns D through J together form the second plateau. The thickness of the intermediate region 330 has been reduced from the first intermediate thickness 339 to a second intermediate thickness 341. The height 833 of the second plateau 832 corresponds to the second intermediate thickness 341 of the intermediate region. As indicated by step 737 of FIG. 39, steps 735 and 740 may be repeated to create any desired number of plateaus.

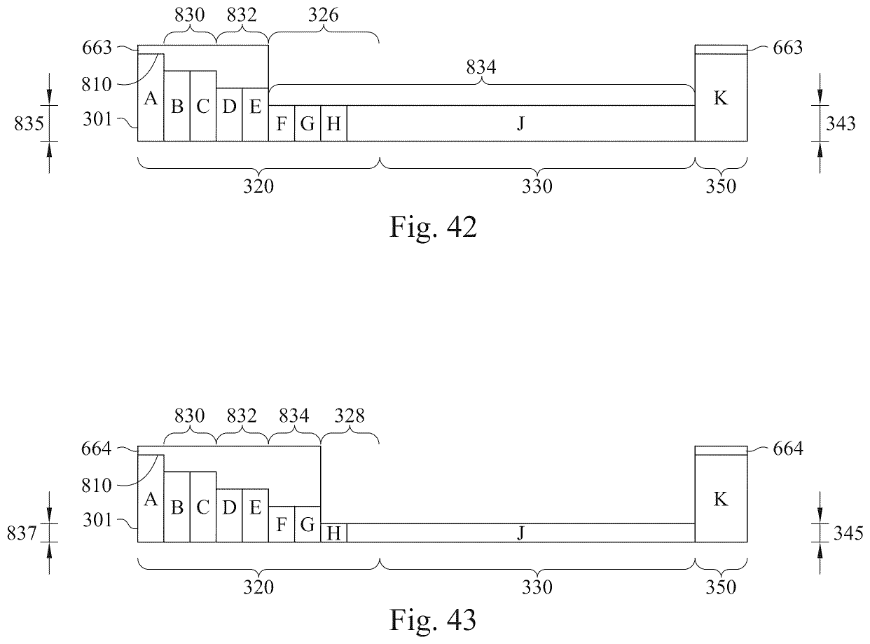

As illustrated in FIG. 42, a third mask 663 is formed over the first side of the substrate 301. The intermediate region 330 and a third portion 326 of the central region 320 is exposed. The third portion 326 surrounds the second portion 324. Then, a third plateau 834 is formed in the central region. This may be done by etching. The third plateau 834 is located below the second plateau 832, and is adjacent to the second plateau 832. Here, the second plateau is now formed by columns D and E, and columns F through J together form the third plateau. The thickness of the intermediate region 330 has been reduced from the second intermediate thickness 341 to a third intermediate thickness 343. The height 835 of the third plateau 834 corresponds to the third intermediate thickness 343 of the intermediate region.

As illustrated in FIG. 43, a fourth mask 664 is formed over the first side of the substrate 301. The intermediate region 330 and a fourth portion 328 of the central region 320 is exposed. Columns H corresponds to the fourth portion. The fourth portion 328 surrounds the third portion 326. After etching, the thickness of the intermediate region 330 has been reduced from the third intermediate thickness 343 to a final thickness 345. The height 837 of column H in the central region corresponds to the final thickness 345 of the intermediate region.

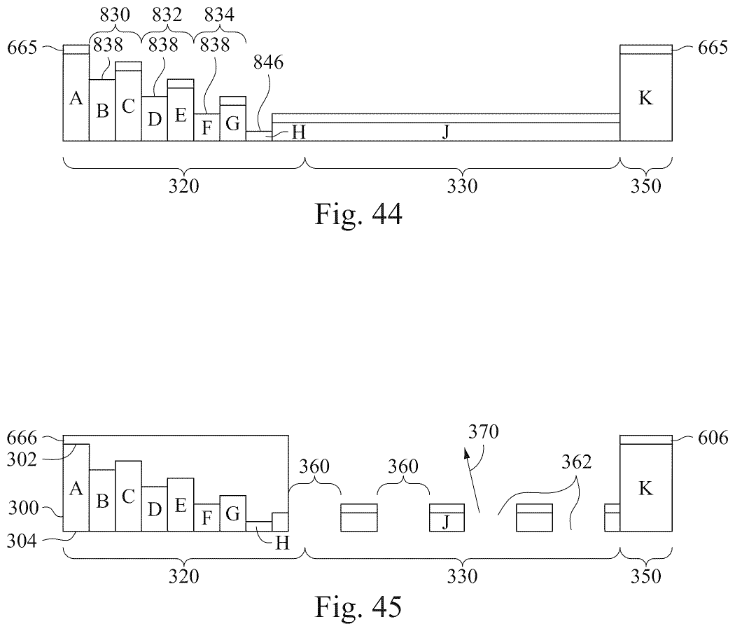

Then, as indicated in step 750 of FIG. 39 and as illustrated in FIG. 44, a fifth mask 665 is formed over the first side of the substrate 301. The fifth mask covers the intermediate region 330 and the perimeter region 350. In the central region 320, the mask exposes an inner portion 838 of each plateau, and covers the outer portion of each plateau. In this illustrated embodiment, the mask also exposes column H. Next, as indicated in step 755 of FIG. 39, a trench or floor is formed in each plateau 830, 832, 834. This may be done by etching. Here, the floors corresponds to columns B, D, and F. A trench 846 is also formed in column H, though this is not required. Steps are defined by the outer portions of each plateau. Here, the steps 820, 822, 824 correspond to columns C, E, and G.

Subsequently, as indicated in optional step 760 of FIG. 39 and as illustrated in FIG. 45, a sixth mask 666 is formed upon the first side of the substrate. The sixth mask covers the central region 320 and the perimeter region 350, and exposes one or more hole regions 360 in the intermediate region 330 of column J. Finally, as indicated in step 765 of FIG. 39, one or more holes 362, such as a plurality of holes, are formed in the hole regions that extend entirely through the substrate 301. A fluid passageway 370 thus extends entirely through the carrier wafer 300 from the first side 302 to the second side 304. This may be done by etching through the sixth mask 666. The resulting structure corresponds to the carrier wafer illustrated in FIG. 37. Again, the last mask 666 does not need to be removed if it is a hard mask (i.e. a thin layer, not as illustrated here). In this regard, it is noted that the fifth mask 665 could also be patterned to expose hole regions 360 in some embodiments where the final thickness 345 of the intermediate region is less than or equal to the trench depths formed in the central region 320, and so a sixth mask may not be needed.

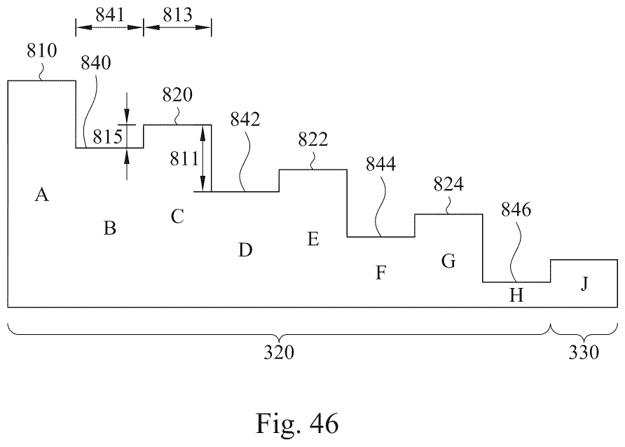

FIG. 46 is a magnified view of the central region 320 and an adjacent portion of the intermediate region 330, and shows more detail. As previously mentioned, there are four steps 810, 820, 822, 824 and four trenches 840, 842, 844, 846. In particular embodiments, each step has a height 811 as measured from the downstream trench of about 2 μm to about 3 μm. In particular embodiments, each step has a cross-sectional length 813 of about 2 μm to about 3 μm. Similarly, in particular embodiments, each trench has a cross-sectional length 841 of about 2 μm to about 3 μm. In particular embodiments, each step has a height 815 as measured from the upstream trench of about 1 μm to about 2 μm. Other ranges and values are also within the scope of the present disclosure.

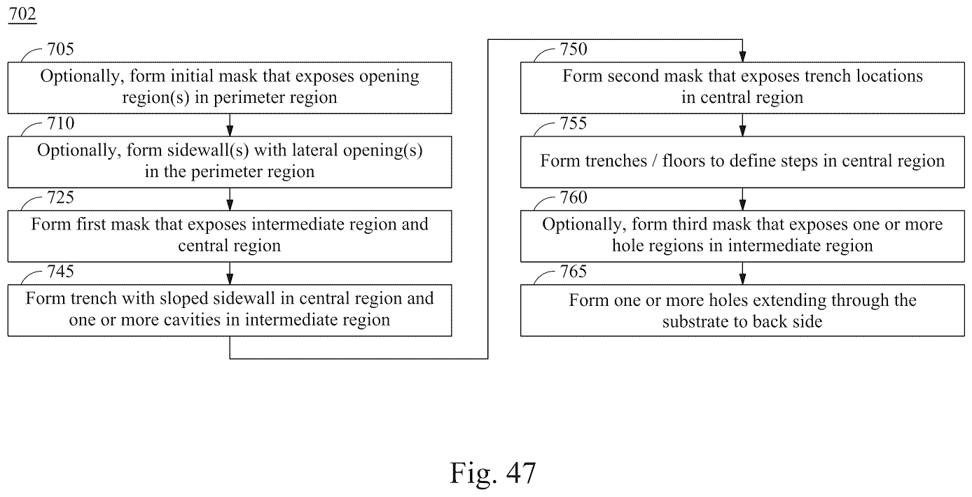

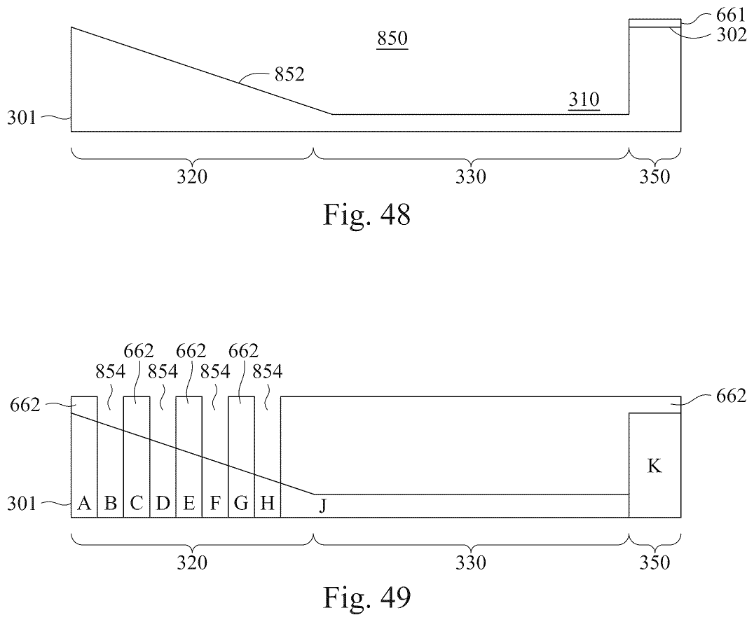

FIG. 47 is a flow chart illustrating another method 702 for making a carrier wafer through which liquid can flow, in accordance with some embodiments. In particular, the carrier wafer includes a plurality of steps in the central region. Some steps of the method are also illustrated in FIGS. 48-53. These figures provide different views for better understanding. While the method steps are discussed below in terms of forming a single carrier wafer, such discussion should also be broadly construed as applying to the concurrent formation of multiple carrier wafers. These figures do not show the formation of the entire carrier wafer, but are illustrated for the portion in the dashed box 218 of FIG. 5A and in FIG. 37. Other structures may also be concurrently formed. It is noted that not all steps described in the flow chart are required, and not all method steps are described in the flow chart.

Initially, if it is desired to form openings 358 as illustrated in the embodiment of FIG. 5B and FIG. 5E, then as indicated in optional step 705 of FIG. 47, an initial mask 660 is formed upon the first side 302 of the substrate. Then, as indicated in optional step 710 of FIG. 47, a sidewall 354 with one or more openings 358 is formed in the perimeter region 350. These steps were previously illustrated, and are not repeated here.

As indicated in step 725 of FIG. 47 and as illustrated in FIG. 48, a first mask 661 is formed over the first side 302 of the substrate 301. The intermediate region 330 and the central region 320 are exposed. The perimeter region 350 is covered. Then, as indicated in step 745 of FIG. 47, a trench 850 is formed that includes a sloped sidewall 852 in the central region 320. The trench extends into the intermediate region 330, and can also be considered a cavity 310 in the intermediate region 330. This may be performed by etching, and more specifically multiple etching steps at different angles to obtain the sloped sidewall. The tapered or sloped sidewall 852 is angled downwards towards the intermediate region 330. The resulting structure is shown in FIG. 48.

Next, after removing the first mask, as indicated in step 750 of FIG. 47 and as illustrated in FIG. 49, a second mask is formed over the first side of the substrate 301. The second mask covers the intermediate region 330 and the perimeter region 350. In the central region 320, trench regions 854 are exposed. The exposed trench regions correspond to columns B, D, F, and H.

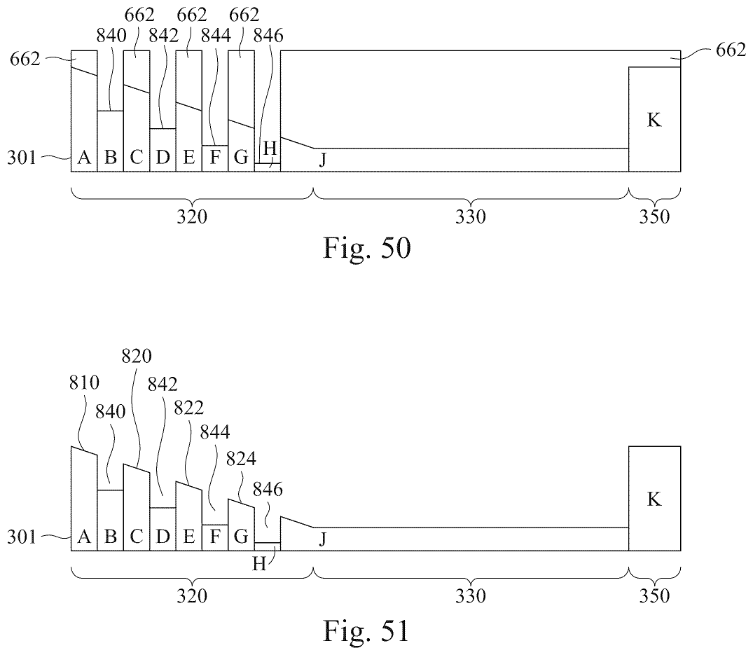

Continuing, as indicated in step 755 of FIG. 47 and as illustrated in FIG. 50, a trench or floor 840, 842, 844, 846 is formed in each trench region. This may be done by etching. Here, the floors corresponds to columns B, D, F, and H. Thus, the steps 810, 820, 822, 824 correspond to columns A, C, E, and G. FIG. 51 illustrates the resulting structure after the second mask is removed.

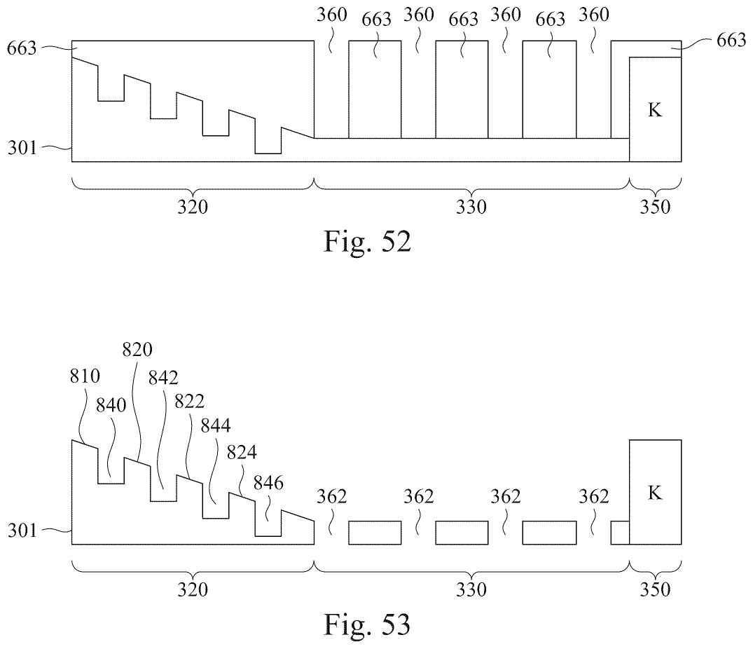

Subsequently, as indicated in optional step 760 of FIG. 47 and as illustrated in FIG. 52, a third mask 663 is formed upon the first side of the substrate. The third mask covers the central region 320 and the perimeter region 350, and exposes one or more hole regions 360 in the intermediate region 330 of column J. Finally, as indicated in step 765 of FIG. 47, one or more holes 362 are formed that extend entirely through the substrate 301. This may be done by etching through the third mask 663. The resulting structure is illustrated in FIG. 53 after the third mask is removed. Again, the last mask 663 does not need to be removed if it is a hard mask (i.e. a thin layer, not as illustrated here). It is also noted that the second mask 662 could also be patterned to expose hole regions 360 in some embodiments where the final thickness 345 of the intermediate region is less than or equal to the trench depths formed in the central region 320, and so a third mask may not be needed.

The structures of the present disclosure have several advantages. Initially, cooling performance is improved. It is estimated that operating temperatures of heat-generating devices may be reduced from, for example, 55° C. to 60° C. without the MEMS cooling devices down to 25° C. with the MEMS cooling devices. In addition, a smaller MEMS cooling device permits the fingers in the arm arrays to be thinner without increasing the risk of breakage. Thus, for an equivalent surface area, more fingers can be obtained using a plurality of smaller MEMS cooling devices rather than one larger MEMS cooling device. Because it is the motion of the fingers which causes liquid flow, more fingers improves liquid flow past the heat-generating device.

Some embodiments of the present disclosure thus relate to methods for cooling a heat-generating device. A package is formed that comprises a plurality of cooling devices attached to a surface of the heat-generating device. Each cooling device comprises an actuator attached to a carrier wafer. The carrier wafer comprises one or more holes that extend through a substrate from a first side to a second side of the substrate. The second side of the carrier wafer is bonded to the surface of the heat-generating device. The cooling fluid can flow between the second side of each carrier wafer and the surface of the heat-generating device. The package may be placed within a housing containing a cooling fluid, such as a dielectric liquid. A MEMS cooling device may also be floated upon the cooling fluid. When operated, the MEMS cooling devices increase the rate at which the cooling fluid flows past the heat-generating device, thus further cooling the heat-generating device.

Other embodiments disclosed herein relate to semiconductor packages, comprising a heat-generating semiconductor device and a plurality of cooling devices attached to a surface of the heat-generating device. Each cooling device comprises an actuator bonded to a carrier wafer. The carrier wafer comprises a substrate having an intermediate region between a perimeter region and a central region of the substrate. The intermediate region has a thickness which is less than a thickness of the perimeter region. At least one cavity is present in the intermediate region in a first side of the substrate. One or more holes in the at least one cavity extend from the first side of the substrate to a second side of the substrate.

Still further embodiments disclosed herein relate to methods for making a semiconductor package. A plurality of cooling devices are adhered to a surface of a heat-generating device. Each cooling device comprises an actuator and a carrier wafer. The carrier wafer comprises one or more holes that extend through a substrate from a first side to a second side of the substrate. The first side of the carrier wafer is bonded to the actuator. The second side of the carrier wafer is bonded to the surface of the heat-generating device by an adhesive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for cooling a heat-generating device, comprising:
placing a package in a cooling fluid;
wherein the package comprises a plurality of cooling devices attached to a surface of the heat-generating device;
wherein each cooling device comprises an actuator attached to a carrier wafer;
wherein the carrier wafer comprises one or more holes that extend through a substrate from a first side to a second side of the substrate; and
wherein the second side of the carrier wafer is bonded to the surface of the heat-generating device to form the package; and
wherein the cooling fluid can flow between the second side of the carrier wafer substrate and the surface of the heat-generating device.

2. The method of claim 1, wherein the cooling fluid is a dielectric liquid.

3. The method of claim 1, wherein the heat-generating device is an interposer, high-bandwidth memory, a CPU, or a GPU.

4. The method of claim 1, wherein the one or more holes independently have a diameter of about 5 μm or more.

5. The method of claim 1, wherein the actuator of each cooling device comprises a first array of fingers and a second array of fingers, the first array of fingers having a greater height than the second array of fingers.

6. The method of claim 5, wherein the second array of fingers move vertically relative to the first array of fingers to induce flow of the cooling fluid through the actuator.

7. The method of claim 6, wherein the cooling devices are synchronized so that when the array of second fingers of one of the cooling devices are moving downwards, the array of second fingers in another of the cooling devices is moving upwards.

8. The method of claim 1, wherein the carrier wafer of at least one of the cooling devices further comprises at least one sidewall with one or more openings in a perimeter region of the substrate.

9. The method of claim 1, wherein the plurality of cooling devices are arranged on the surface of the heat-generating device with gaps between the cooling devices.

10. The method of claim 1, wherein a central region of the carrier wafer includes a plurality of steps extending downwards towards an intermediate region.

11. The method of claim 10, wherein each step has a height of about 2 μm to about 3 μm, and has a cross-sectional length of about 2 μm to about 3 μm.

12. The method of claim 1, wherein the one or more holes are formed in at least one cavity in the carrier wafer.

13. The method of claim 1, wherein each carrier wafer has a length of about 30 μm or greater, and has a width of about 30 μm or greater.

14. A semiconductor package, comprising:
a heat-generating semiconductor device; and
a plurality of cooling devices attached to a surface of the heat-generating device;
wherein each cooling device comprises an actuator bonded to a carrier wafer, wherein the carrier wafer comprises;
a substrate having an intermediate region between a perimeter region and a central region of the substrate, wherein the intermediate region has a thickness which is less than a thickness of the perimeter region;
at least one cavity in the intermediate region in a first side of the substrate; and
one or more holes in the at least one cavity that extend from the first side of the substrate to a second side of the substrate.

15. The package of claim 14, wherein the actuator comprises a first array of fingers and a second array of fingers, the first array of fingers having a greater height than the second array of fingers.

16. The package of claim 15, wherein the first array of fingers and the second array of fingers comprise a piezoelectric material.

17. The package of claim 14, wherein the one or more holes include a first hole and a second hole that have different surface areas or different shapes in a plan view.

18. A method for making a semiconductor package, comprising:
adhering a plurality of cooling devices to a surface of a heat-generating device;
wherein each cooling device comprises an actuator and a carrier wafer;
wherein the carrier wafer comprises one or more holes that extend through a substrate from a first side to a second side of the substrate;
wherein the first side of the carrier wafer is bonded to the actuator; and
wherein the second side of the carrier wafer is bonded to the surface of the heat-generating device by an adhesive layer.

19. The method of claim 18, wherein the adhesive layer has a thickness of about three micrometers or more.

20. The method of claim 18, wherein the carrier wafer further comprises at least one sidewall with one or more openings in a perimeter region of the substrate.
